(19) United States
(12) Patent Application Publication
(10) Pub. No.: US 2006/0192213 A1
(43) Pub. Date: Aug. 31, 2006

(54) Light-emitting device

(75) Inventors: Iwao Ohwada, Nagoya-City (JP); Tetsuyuki Kameji, Nagoya-City (JP); Hirokazu Nakamura, Ama-Gun (JP)

Correspondence Address: BURR & BROWN, PO BOX 7068, SYRACUSE, NY, 13261-7068, US

(73) Assignee: NGK Insulators, Ltd., Nagoya-City (JP)

(21) Appl. No.: 11/360,249

(22) Filed: Feb. 23, 2006

(30) Foreign Application Priority Data
Feb. 25, 2005 (JP) 2005-050581

(51) Int. Cl. H01L 33/00

(52) U.S. Cl. 257/79

(57) ABSTRACT

A light-emitting device includes electron emitters for planarly emitting electrons, collector electrodes disposed to face corresponding one electron emitter, and a phosphor formed near the collector electrodes. During a period when electrons are emitted from the electron emitter, a collector voltage is applied to each of the collector electrodes in the sequence. Electrons are attracted toward a region of the phosphor in the vicinity of the collector electrode to which the collector voltage is applied, and impinge on the region of the phosphor, whereby light is emitted therefrom. The remaining region of the phosphor emit afterglow.

### BACKGROUND OF THE INVENTION

1. Field of the Invention

The present invention relates to a light-emitting device including an electron emitter (electron emitting element) which planarly emits a large number of electrons, and a phosphor which emits light through impingement thereon of electrons emitted from the electron emitter (electron emitting element).

2. Description of the Related Art

Conventionally, various light-emitting devices have been developed for use as, for example, light sources for backlights of liquid crystal displays. Among the light-emitting devices, one which uses cold cathode lamps (refer to, for example, Japanese Patent Application Laid-Open (kokai) No. 2004-235103 (Paragraphs 0019 and 0020)) includes, as shown in FIG. 25, tubular cold cathode lamps 201. The device includes a diffusion plate 202, a diffusion sheet 203, a BEF 204 and a DBEF 205, all disposed in opposition to the cold cathode lamps 201. The device further includes a reflection sheet 206 disposed such that the cold cathode lamps 201 are interposed between the same and the diffusion plate 202.

Such a light-emitting device using the cold cathode lamps involves the following problems to be solved:
Because of use of mercury (Hg), use of the cold cathode lamps is unfavorable in terms of the environment.
The cold cathode lamp emits light linearly (or in a rod-like fashion). Accordingly, even when a plurality of cold cathode lamps are used, bright regions and dark regions (uneven emission of light or uneven brightness) arise. Such a light-emitting device involving uneven emission of light is unfavorable as a light source for a backlight of a liquid crystal display or the like. Accordingly, in order to evenly emit light through diffusion of light and the like, not only the diffusion plate 202 but also many films, such as the diffusion sheet 203, the BEF 204, and the DBEF 205, are required, resulting in an increase in a thickness L of the light-emitting device and an increase in cost.

Meanwhile, there has been developed an electron emitter including an emitter section, which is formed from a sheet-like dielectric material; a lower electrode, which is formed under the emitter section; and an upper electrode, which is formed on the emitter section in such a manner as to face the lower electrode with the emitter section sandwiched therebetween and in which a plurality of fine through holes are formed. When a predetermined write voltage is applied between the lower electrode and the upper electrode, electrons are accumulated in the emitter section. When a predetermined electron emission voltage is applied between the lower electrode and the upper electrode, the accumulated electrons are planarly emitted through the fine through holes formed in the upper electrode. Accordingly, when a phosphor which emits light through impingement of electrons is disposed in opposition to the electron emitter, the phosphor can be caused to planarly emit light. Thus, a light-emitting device which employs such an electron emitter can solve the above-mentioned problems (environmental problem and uneven emission of light).

Generally, the above-mentioned phosphor enters an excited state through impingement of electrons. In transition from the excited state to the ground state, the phosphor emits light. Accordingly, by continuously applying the electron emission voltage to the electron emitter so as to increase the quantity of electrons impinging on the phosphor, the quantity of light emission (brightness) can be increased. However, when excess electrons impinge on the phosphor, excess energy associated with the excess electrons changes to heat, so that the quantity of light emission does not increase. In other words, excess power involved in application of the electron emission voltage to the electron emitter changes to heat and is thus wasted without any contribution to the phosphor's emission of light.

### SUMMARY OF THE INVENTION

In view of the foregoing, one of objects of the present invention is to provide a light-emitting device using an electron emitter for planarly emitting electrons as mentioned above, exhibiting low power consumption, and capable of providing even brightness as well as a large quantity of light emission (high brightness). The light-emitting device of the present invention can be applied to a wide range of devices and apparatus, such as not only light sources for backlights of liquid crystal displays but also pixels (light-emitting elements which emit light in colors such as RGB) of color display units, and turn signal lamps and stop lamps of vehicles.

To achieve the above object, a light-emitting device according to the present invention comprises an electron emitter (an electron emitter element) for accumulating therein a large number of electrons upon application of a predetermined write voltage thereto and for planarly emitting the accumulated large number of electrons from a planar electron-emitting section thereof upon application of a predetermined electron emission voltage thereto; a plurality of collector electrodes disposed in opposition to the electron-emitting section and adapted to attract, upon application of a predetermined collector voltage thereto, electrons emitted from the electron emitter; a phosphor disposed in the vicinity of the plurality of collector electrodes and emitting light through impingement of electrons thereon; an electron emission drive circuit for alternately applying the write voltage and the electron emission voltage to the electron emitter; and a collector voltage application circuit for applying the collector voltage to the plurality of collector electrodes in respective different periods of time during emission of electrons by the electron emitter.

According to the present invention, the electron emitter accumulates electrons therein when the write voltage is applied thereto, and planarly emits the accumulated electrons when the electron emission voltage is applied thereto. The emitted electrodes are attracted to the collector electrode to which the collector voltage is applied. As a result, the electrons impinge on the phosphor in a region located in the vicinity of the collector electrode, and the region of the phosphor on which the electrons impinge emits light. Subsequently, the collector voltage applied to the collector electrode is removed. Accordingly, electrons do not impinge on the region of the phosphor located in the vicinity of the collector electrode. However, the region of the phosphor emits afterglow (i.e., emits remaining light) for a while.

Meanwhile, the collector voltage is applied to the plurality of collector electrodes in respective different periods of time. Accordingly, while the phosphor is emitting afterglow from one region, the collector voltage is applied to another collector electrode. Electrons impinge on the phosphor in another region located in the vicinity of the collector electrode to which the collector voltage is applied, and the region of the phosphor on which electrons impinge emits light. In this manner, the light-emitting device of the present invention can utilize afterglow emitted from a certain region of the phosphor and light emitted from another region of the phosphor on which electrons impinge. Thus, a large quantity of light can be emitted without impingement of excess electrons on the phosphor (in other words, without waste of power to be applied to the electron emitter). Utilization of afterglow means that even after energy applied for exciting the phosphor becomes zero, a certain quantity of light is obtained (light is emitted), thereby contributing to an increase in light emission efficiency of the phosphor (i.e., the efficiency being quantity of light emission/energy applied to phosphor is improved).

Preferably, during application of the collector voltage to one of the plurality of collector electrodes, the collector voltage application circuit does not apply the collector voltage to the remaining collector electrodes.

According to this feature, electrons emitted from the electron emitter can be reliably attracted to any of the collector electrodes. Accordingly, a region of the phosphor located in the vicinity of a collector electrode attracting electrons can reliably emit light.

Preferably, the collector voltage application circuit repeats an operation of applying the collector voltage to each of the plurality of collector electrodes in a predetermined sequence.

According to this feature, before the quantity of afterglow of a region of the phosphor located in the vicinity of a certain collector electrode becomes excessively small, the region of the phosphor can emit light again through impingement of electrons thereon. As a result, uneven emission of light (uneven brightness) can be reduced.

Preferably, the electron emission drive circuit applies the electron emission voltage to the electron emitter only while the collector voltage is applied to any of the plurality of collector electrodes, and applies the write voltage to the electron emitter only while the collector voltage is applied to none of the plurality of collector electrodes.

According to this feature, while the collector voltage is applied to any one of the plurality of collector electrodes, the electron emission voltage is applied to the electron emitter, so that electrons are emitted. In other words, this can avoid an occurrence in which, in spite of emission of no electrons, the collector voltage is applied to a collector electrode. As a result, wasteful consumption of power in the collector voltage application circuit can be avoided. Additionally, while the collector voltage is applied to none of the plurality of collector electrodes, the write voltage is applied to the electron emitter. Accordingly, while there is no need to subject the phosphor to impingement by electrons, the electron emitter can accumulate electrons therein. As a result, electrons can be efficiently accumulated in the electron emitter and can be efficiently emitted. Also, since, while the write voltage is applied to the electron emitter, application of a strong electric field associated with the collector voltage between the collector electrode and the upper electrode can be avoided, wear (deterioration) of the upper electrode and dielectric breakdown of the electron emitter can be prevented.

Further, the collector voltage application circuit can be configured so as to apply the collector voltage at least once to each of the plurality of collector electrodes during a period of time between start and end of application of the electron emission voltage by the electron emission drive circuit.

According to this feature, a single continuous emission of electrons from the electron emitter can cause the phosphor to emit light at least once in all regions located in the vicinity of the corresponding collector electrodes.

The above-mentioned light-emitting device may be such that the phosphor is a white phosphor for emitting white light. This allows provision of a light-emitting device (light source) which can be readily used as a backlight source for a liquid crystal display or the like.

The above-mentioned light-emitting device may be such that a plurality of the phosphors are provided and such that the plurality of phosphors are disposed in the vicinity of the corresponding collector electrodes and emit lights having different colors. This enables provision of a light-emitting device which emits light in different colors.

The above-mentioned light-emitting device may be such that the collector electrodes are provided in a number of at least three; the phosphors are provided in a number of at least three; the three phosphors are disposed in the vicinity of the corresponding three collector electrodes; one of the three phosphors is a red phosphor for emitting red light; another one of the three phosphors is a green phosphor for emitting green light; and the remaining one of the three phosphors is a blue phosphor for emitting blue light. This enables provision of a device which form pixels each made up of so-called RGB phosphor cells. Accordingly, the light-emitting device can be used in a color display.

In a conventional device which forms pixels of a color display, first, white light is emitted, and then the white light passes through red, green, and blue color filters, whereby light of a desired color is obtained. However, white light contains light of other colors (e.g., yellow). Light which is contained in white light and cannot pass through the color filters has no effect in terms of an increase in the quantity of light emission (brightness), and is thus emitted in vain. In other words, the conventional device wastefully consumes power as a result of emission of white light. By contrast, in the light-emitting device configured as mentioned above, a phosphor which emits light of a desired color is subjected to impingement of electrons, so that light is not wastefully emitted. Accordingly, power consumption of the light-emitting device can be reduced. Further, preferably, the above-mentioned configuration employing the phosphors in three colors is used as the configuration of a light source for a backlight of a liquid crystal display. This case is advantageous in that, as compared with the case where only the white phosphor is used, spectrum characteristics can be more readily rendered compatible with (or suitable for the characteristics of) the color filters. Further, light in three primary colors can be emitted on a time-division basis corresponding to a “field sequential system,” in which one frame time is divided into three segments which are allocated to display of individual monochromatic images in red, green, and blue.

Further, the above-mentioned light-emitting device can further comprise a sheet-like transparent plate having a lower surface in opposition to the electron-emitting section and in parallel with a plane of the electron-emitting section, a reflection plate or a scattering plate, and a plurality of the electron emitters. In this case, preferably, the plurality of collector electrodes, and the phosphor are formed on the lower surface of the transparent plate; the reflection plate or the scattering plate is disposed at a position avoiding hindrance to travel of electrons emitted from the electron emitters and directed toward the plurality of collector electrodes, and in opposition to the transparent plate and the collector electrodes; and the transparent plate has a light transmission portion formed at a position located between an end collector electrode of one group of collector electrodes attracting electrons emitted from a first one of the plurality of electron emitters and an end collection electrode, adjacent to the first-mentioned end collector electrode, of another group of collector electrodes attracting electrons emitted from a second one of the plurality of electron emitters, the light transmission portion allowing transmission therethrough of light reflected from the reflection plate or the scattering plate.

A portion of light emitted by the phosphor is directly emitted to the exterior of the light-emitting device through the transparent plate. However, most of light emitted by the phosphor is scattered and directed toward a side associated with the electron emitters (i.e., toward the interior of the light-emitting device). Through employment of the above-mentioned configuration where the light transmission portion is formed in the transparent plate, and the reflection plate or the scattering plate is disposed, light scattered and directed toward the side associated with the electron emitters can be reflected by the reflection plate or the scattering plate so as to be directed again toward the transparent plate, and emitted to the exterior of the light-emitting device through the light transmission portion. This allows provision of a light-emitting device which can emit a large quantity of light with smaller power consumption.

Disposition of the reflection plate or the scattering plate at a position avoiding hindrance to travel of electrons emitted from the electron emitters includes the following configurations. The reflection plate or the scattering plate is disposed or formed such that the mirror surface of the reflection plate or the scattering surface of the scattering plate is flush with the surface of the electron-emitting sections of the electron emitters. When the electron emitters are formed on the upper surface of a transparent substrate, the reflection plate or the scattering plate is disposed or formed such that the mirror surface or the scattering surface is present on the lower surface of the substrate.

The above-mentioned electron emitter can be such that it comprises an emitter section formed of a sheet-like dielectric material, a lower electrode formed under the emitter section, and an upper electrode serving as the electron-emitting section, formed on the emitter section in such a manner as to face the lower electrode with the emitter section sandwiched therebetween, and having a plurality of fine through holes formed therein; accumulates, when the write voltage is applied between the lower electrode and the upper electrode, the large number of electrons at an upper portion of the emitter section through negative-side polarization inversion of the emitter section effected by the write voltage; and planarly emits, when the electron emission voltage is applied between the lower electrode and the upper electrode, the accumulated large number of electrons through the fine though holes of the upper electrode through positive-side polarization inversion of the emitter section effected by the electron emission voltage.

### BRIEF DESCRIPTION OF THE DRAWINGS

Various other objects, features and many of the attendant advantages of the present invention will be readily appreciated as the same becomes better understood by reference to the following detailed description of the preferred embodiments when considered in connection with the accompanying drawings, in which:

FIG. 1 is a fragmentary, sectional view of a light-emitting device according to a first embodiment of the present invention;

FIG. 2 is a fragmentary plan view of the light-emitting device shown in FIG. 1;

FIG. 3 is an enlarged fragmentary, sectional view of an electron emitter shown in FIG. 1;

FIG. 4 is an enlarged fragmentary, plan view of an electron emitter shown in FIG. 1;

FIG. 5 is a circuit diagram of the light-emitting device shown in FIG. 1;

FIG. 6 is a view showing a state of the light-emitting device shown in FIG. 1;

FIG. 7 is a graph of a voltage-polarization characteristic of an emitter section of the light-emitting device shown in FIG. 1;

FIG. 8 is a view showing another state of the light-emitting device shown in FIG. 1;

FIG. 9 is a view showing a further state of the light-emitting device shown in FIG. 1;

FIG. 10 is a view showing a still further state of the light-emitting device shown in FIG. 1;

FIG. 11 is a view showing yet another state of the light-emitting device shown in FIG. 1;

FIG. 12 is a view showing another state of the light-emitting device shown in FIG. 1;

FIG. 13 is a time chart showing an operation of the light-emitting device shown in FIG. 1;

FIG. 14 is a time chart showing an operation of a light-emitting device according to a second embodiment of the present invention;

FIG. 15A is a fragmentary plan view of a light-emitting device according to a third embodiment of the present invention;

FIG. 15B is a fragmentary, sectional view of the light-emitting device shown in FIG. 15A;

FIG. 16A is a fragmentary plan view of a light-emitting device according to a first modified embodiment of the third embodiment of the present invention;

FIG. 16B is a fragmentary, sectional view of the light-emitting device shown in FIG. 16A;

FIG. 17 is a fragmentary plan view of a light-emitting device according to a second modified embodiment of the third embodiment of the present invention;

FIG. 18 is a fragmentary plan view of electron emitters and a reflection plate (or a scattering plate) of the light-emitting device shown in FIG. 17;

FIG. 19 is a fragmentary, sectional view of a light-emitting device according to a fourth embodiment of the present invention;

FIG. 20 is a fragmentary plan view of the light-emitting device shown in FIG. 19;

FIG. 21 is a time chart showing an operation of the light-emitting device shown in FIG. 19;

FIG. 22 is a time chart showing another operation of the light-emitting device shown in FIG. 19;

FIG. 23 is a fragmentary, sectional view of another modified embodiment of a light-emitting device according to the present invention;

FIG. 24 is a sectional view of a transparent plate, a phosphor, and a collector electrode of still another modified embodiment of a light-emitting device according to the present invention; and

FIG. 25 is a fragmentary, sectional view of a conventional light source using cold cathode lamps.

### DESCRIPTION OF THE PREFERRED EMBODIMENTS

Embodiments of a light-emitting device according to the present invention will next be described in detail with reference to the drawings.

First Embodiment:

Structure:

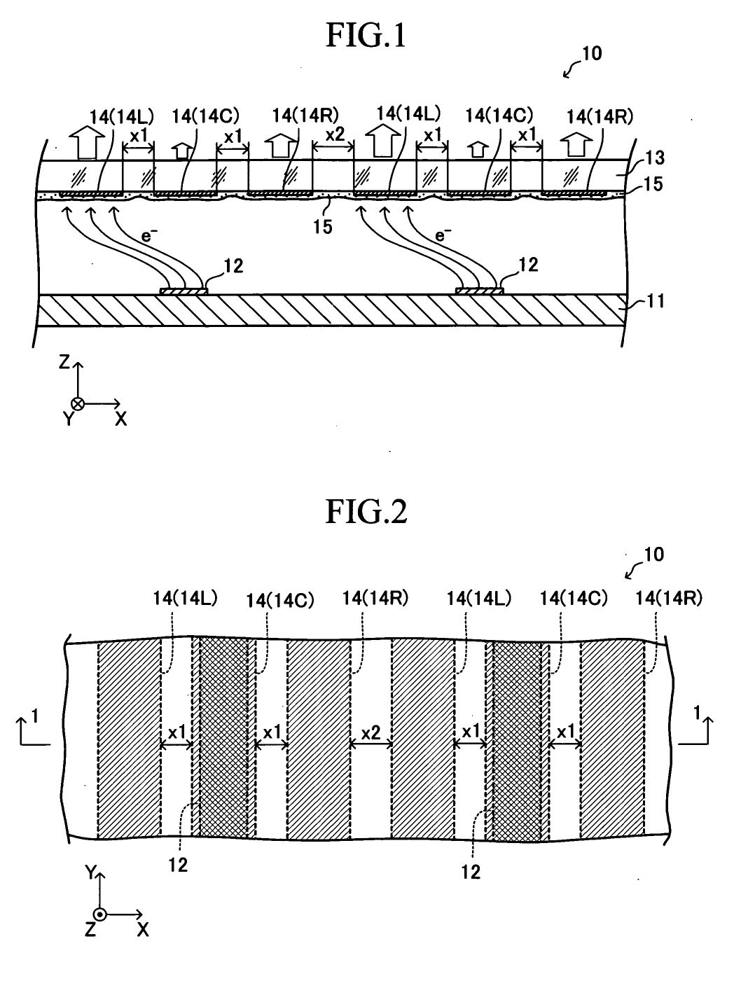

As shown in FIG. 1, which is a fragmentary, sectional view, and FIG. 2, which is a fragmentary plan view, a light-emitting device 10 according to a first embodiment of the present invention includes a substrate 11, a plurality of electron emitters (electron emitting elements) 12, a transparent plate (light-emitting substrate) 13, a plurality of collector electrodes 14, and a phosphor 15. FIG. 1 is a sectional view of the light-emitting device 10 cut by a plane extending along line 1-1 of FIG. 2.

The substrate 11 is a sheet-like member having an upper surface and a lower surface in parallel with a plane (X-Y plane) defined by mutually orthogonal X-and Y-axes and having a thickness in the direction of a Z-axis orthogonal to the X- and Y-axes. The substrate 11 is formed from, for example, a material (e.g., glass or ceramic materials) whose main component is zirconium oxide.

The electron emitter 12 has a small thickness in the direction of the Z-axis and extends in the direction of the Y-axis while having a constant width in the direction of the X-axis. A plurality of the electron emitters 12 are formed on the upper surface of the substrate 11 at predetermined intervals along the direction of the X-axis. As will be described in detail later, each of the electron emitters 12 accumulates a large number of electrons therein when a predetermined write voltage is applied thereto, and emits upward (in the positive direction of the Z-axis) the accumulated large number of electrons in a planar fashion from its planar electron-emitting section. The electron-emitting section is an upper electrode, which will be described later, formed on an upper portion of the electron emitter 12.

The transparent plate 13 is a sheet-like member having an upper surface and a lower surface in parallel with each other and having a thickness in a direction orthogonal to the upper and lower surfaces. The transparent plate 13 is formed from a transparent material (herein, glass or acrylic). The transparent plate 13 is disposed respective predetermined distances above (in the positive direction of the Z-axis) the substrate 11 and the electron emitters 12. The transparent plate 13 is disposed such that its lower surface is in parallel with a plane formed by the electron-emitting sections of the electron emitters 12 (i.e., such that the lower surface extends along the X-Y plane).

The collector electrodes 14 are formed from an electrically conductive substance (herein, a transparent, electrically conductive film of ITO). The collector electrodes 14 are formed and fixed on the lower surface of the transparent plate 13. Each of the collector electrodes 14 has a small thickness in the direction of the Z-axis and extends in the direction of the Y-axis while having a constant width in the direction of the X-axis, the width being slightly greater than that of the electron emitter 12.

Specifically, three collector electrodes 14 are provided for a single electron emitter 12. For convenience of description, the three collector electrodes 14 are individually called a center collector electrode 14C, a left collector electrode 14L, and a right collector electrode 14R. These collector electrodes 14C, 14L, and 14R have the same shape.

As shown in FIG. 2, the center collector electrode 14C is disposed such that, as viewed in plane, its axis along the direction of the Y-axis coincides with that of the corresponding electron emitter 12. The left collector electrode 14L is formed a predetermined distance x1 apart in the negative direction of the X-axis from the center collector electrode 14C. The right collector electrode 14R is formed the predetermined distance x1 apart in the positive direction of the X-axis from the center collector electrode 14C. The right collector electrode 14R is formed a distance x2, which is equal to or greater than the distance x1, apart from the adjacent left collector electrode 14L, the adjacent left collector electrode 14L being adjacently located in the positive direction of the X-axis.

The phosphor 15 is formed in a film-like fashion on the lower surface of the transparent plate 13 and covers the plurality of collector electrodes 14. The phosphor enters an excited state through impingement of electrons thereon. In transition from the excited state to the ground state, the phosphor 15 emits white light. A typical example of such a white phosphor is Y₂O₂S:Tb. Alternatively, the white phosphor can be prepared by mixing a red phosphor (e.g., Y₂O₂S:Eu), a green phosphor (e.g., ZnS:Cu, Al), and a blue phosphor (e.g., ZnS:Ag, Cl). Light emitted from the phosphor 15 travels upward (toward the exterior) of the light-emitting device 10 through the transparent plate 13.

A space surrounded by the substrate 11, the electron emitters 12 and the phosphor 15 is held substantially in a vacuum (preferably 10² to 10⁻⁶ Pa, more preferably 10⁻³ to 10⁻⁵ Pa). In other words, the substrate 11, the electron emitters 12, and the transparent plate 13 are space formation members which, together with unillustrated side wall portions of the light-emitting device 10, define a closed space. The closed space is held substantially in a vacuum. Accordingly, the electron emitters 12 are disposed within the closed space, which is held substantially in a vacuum by means of the space formation members.

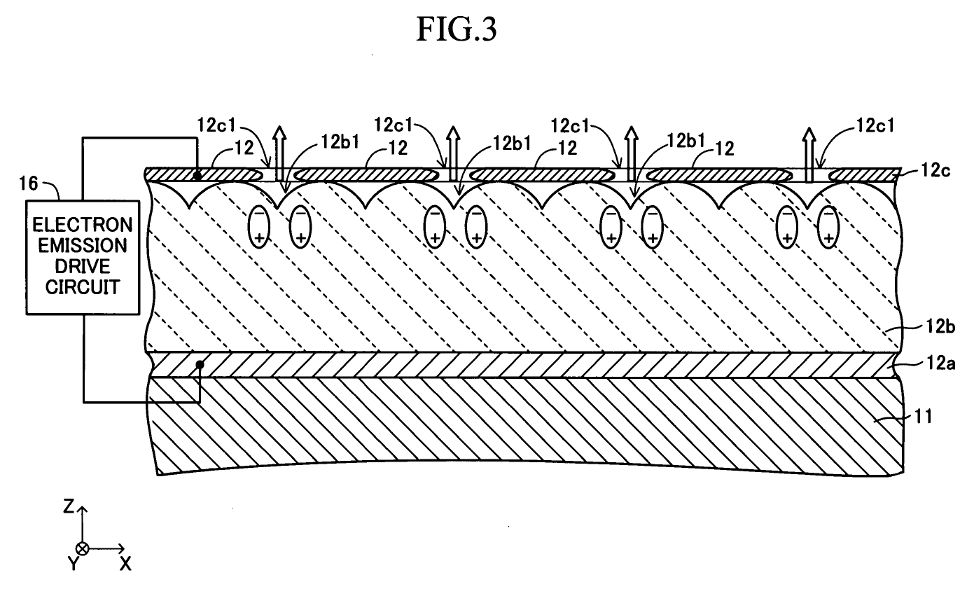

The electron emitter 12 will next be described with reference to FIG. 3, which is a sectional view of the electron emitter 12. The electron emitter 12 includes a lower electrode (lower electrode layer) 12a formed on the substrate 11, an emitter section 12b, and an upper electrode (upper electrode layer) 12c. A material used to form the electron emitter 12 and a method for manufacturing the electron emitter 12 will be described later in detail.

The lower electrode 12a is formed in a layer fashion from an electrically conductive substance (herein, silver or platinum) on the upper surface of the substrate 11. As viewed in plane, the lower electrode 12a has a strip-like shape whose longitudinal direction extends in the direction of the Y-axis.

The emitter section 12b is made of a dielectric material having a high relative dielectric constant (for example, a three-component material PMN-PT-PZ composed of lead magnesium niobate (PMN), lead titanate (PT), and lead zirconate (PZ)) and is formed on the upper surface of the lower electrode 12a. The emitter section 12b is a sheet-like member having a thickness in the direction of the Z-axis and has the same shape as that of the lower electrode 12a as viewed in plane. Concavities and convexities 12b1 associated with grain boundaries of the dielectric material are formed on the upper surface of the emitter section 12b.

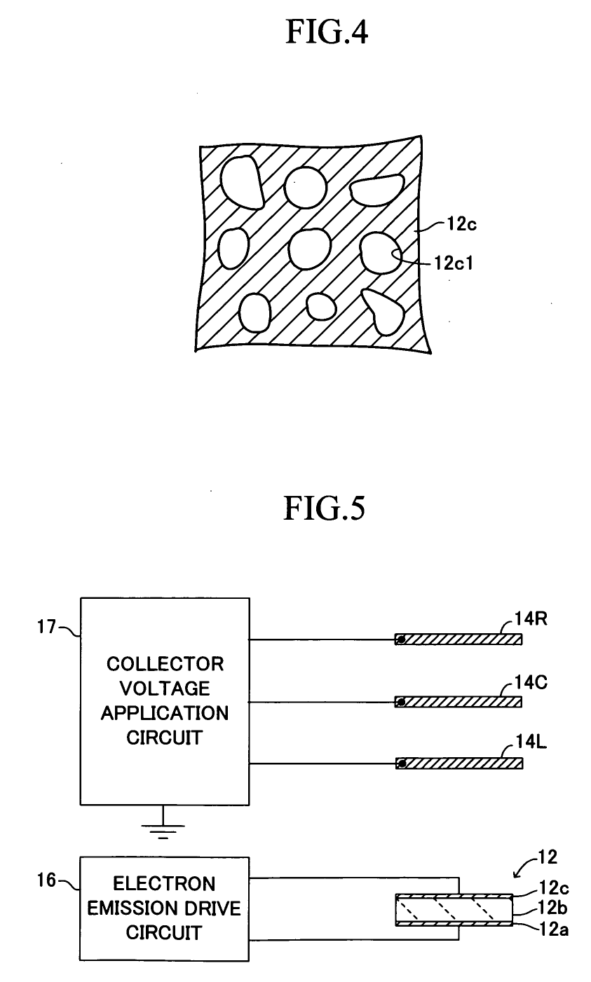

The upper electrode 12c is formed in a layer fashion from an electrically conductive substance (herein, platinum) on an upper portion of the emitter section 12b (on the upper surface of the emitter section 12b) in such a manner as to face the lower electrode 12a with the emitter section 12b sandwiched therebetween. As viewed in plane, the upper electrode 12c has substantially the same shape as those of the lower electrode 12a and the emitter section 12b. Further, as shown in FIG. 3, and FIG. 4, which is a fragmentary, enlarged plan view of the upper electrode 12c, a plurality of fine through holes 12c1 are formed in the upper electrode 12c.

The lower electrode 12a, the emitter section 12b, and the upper electrode 12c formed from platinum resinate paste are integrated together by a firing process. During the firing process for integration, a film to become the upper electrode 12c shrinks in thickness; for example, from 10 μm to 0.1 μm. At this time, the plurality of fine through holes 12c1 are formed in the upper electrode 12c.

As shown in FIG. 5, which is a circuit diagram, the light-emitting device 10 includes an electron emission drive circuit 16 and a collector voltage application circuit 17. Notably, FIG. 5 only shows a single electron emitter 12 and three collector electrodes 14 (14L, 14C, and 14R) for collecting electrons emitted from the single electron emitter 12.

The electron emission drive circuit 16 is connected to the lower electrode 12a and the upper electrode 12c and is designed to apply a drive voltage Vin to the electron emitter 12. Specifically, the electron emission drive circuit 16 alternately generates, as the drive voltage Vin, a write voltage Vm and an electron emission voltage Vp and alternately applies the voltages Vm and Vp to the electron emitter 12 (between the lower electrode 12a and the upper electrode 12c).

The write voltage Vm initiates negative-side polarization inversion in the emitter section 12b so as to accumulate a large number of electrons at an upper portion of the emitter section 12b. The write voltage Vm is applied so that the electric potential of the upper electrode 12c becomes lower than the reference potential of the lower electrode 12a by a positive voltage |Vm|.

The electron emission voltage Vp initiates positive-side polarization inversion in the emitter section 12b so as to planarly emit a large number of electrons accumulated at the upper portion of the emitter section 12b, through the fine through holes 12c1 of the upper electrode 12c. The electron emission voltage Vp is applied so that the electric potential of the upper electrode 12c becomes higher than the reference potential of the lower electrode 12a by a positive voltage Vp.

The collector voltage application circuit 17 is connected to each of the plurality of collector electrodes 14. The collector voltage application circuit 17 applies a predetermined collector voltage Vc (voltage having a rectangular pulse shape) to the plurality of collector electrodes 14 in respective different periods of time during emission of electrons by the electron emitter 12.

Principle and Operation of Electron Emission:

Next, the principle of operation of the electron emitter 12 configured as described above will be described.

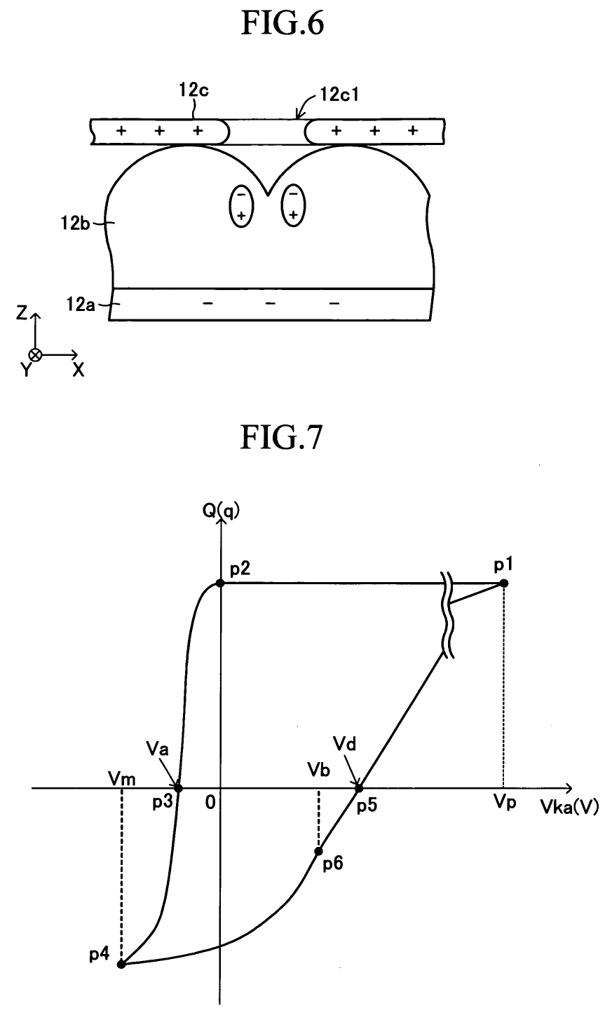

First, description starts with a state shown in FIG. 6. In the state, an actual electric-potential difference Vka (element voltage Vka) between the lower electrode 12a, whose electric potential serves as a reference potential, and the upper electrode 12c is held at a positive predetermined voltage Vp. The state arises immediately after electrons accumulated in the emitter section 12b are all emitted; i.e., in this state, no electrons are accumulated in the emitter section 12b. In this state, the negative poles of dipoles in the emitter section 12b face toward the upper surface of the emitter section 12b (in the positive direction of the Z-axis; i.e., toward the upper electrode 12c). This state is at a point p1 on a graph shown in FIG. 7. The graph of FIG. 7 shows a voltage-polarization characteristic of the emitter section 12b. In the graph of FIG. 7, the element voltage Vka is plotted along the horizontal axis, and a charge Q in the vicinity of the upper electrode 12c is plotted along the vertical axis.

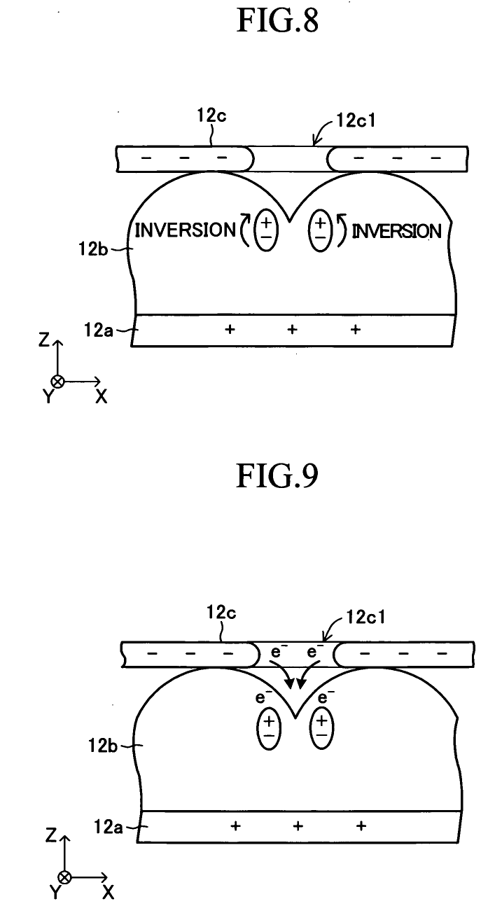

In this state, the electron emission drive circuit 16 changes the drive voltage Vin to the write voltage Vm, which is a negative predetermined voltage. This causes the element voltage Vka to decrease toward a point p3 via a point p2 in FIG. 7. When the element voltage Vka decreases to a voltage near a negative coercive electric-field voltage Va shown in FIG. 7, the direction of dipoles in the emitter section 12b begins to be inverted. Specifically, as shown in FIG. 8, polarization inversion (negative-side polarization inversion) begins.

The negative-side polarization inversion increases the intensity of electric field (electric field concentration occurs) in a contact region (triple junction) among the upper surface of the emitter section 12b, the upper electrode 12c, and their ambient medium (in this case, vacuum) and/or at a tip end portion of the upper electrode 12c which defines the fine through hole 12c1. As a result, as shown in FIG. 9, the upper electrode 12c begins to supply electrons toward the emitter section 12b.

The thus-supplied electrons are accumulated mainly in the vicinity of a region of an upper portion of the emitter section 12b which is exposed through the fine through hole 12c1, and in the vicinity of an end portion of the upper electrode 12c which defines the fine through hole 12c1 (hereinafter, may be referred to merely as “vicinity of the fine through hole 12c1”). Subsequently, when negative-side polarization inversion is completed after elapse of a predetermined time, the element voltage Vka sharply changes to the negative predetermined voltage Vm. As a result, accumulation of electrons is completed (a state in which accumulation of electrons is saturated is reached). This state is at a point p4 in FIG. 7.

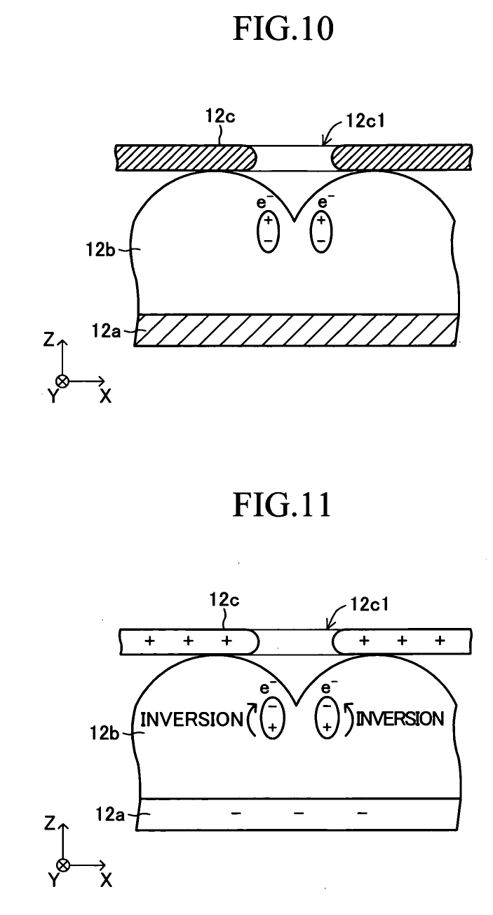

Next, when electron emission timing is reached, the electron emission drive circuit 16 changes the drive voltage Vin to the electron emission voltage Vp, which is a positive predetermined voltage. This initiates an increase in the element voltage Vka. The emitter section 12b holds its charged state as shown in FIG. 10 until the element voltage Vka reaches a voltage Vb (point p6), which is slightly lower than a positive coercive electric-field voltage Vd corresponding to a point p5 in FIG. 7.

Subsequently, the element voltage Vka reaches a voltage near the positive coercive electric-field voltage Vd. This causes dipoles to begin to turn around such that their negative poles face toward the upper surface of the emitter section 12b. In other words, as shown in FIG. 11, dipoles are inverted again (positive-side polarization inversion begins). This state is near a point p5 in FIG. 7.

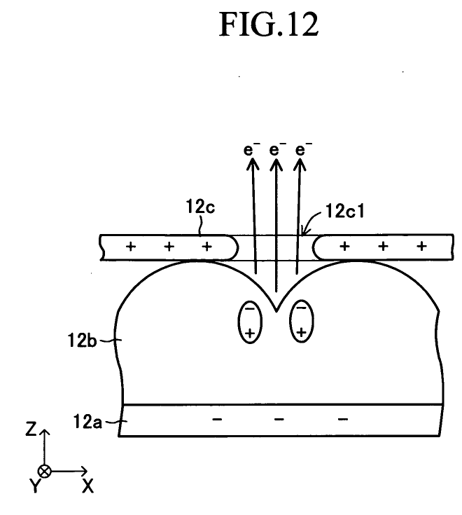

Subsequently, when positive-side polarization inversion is about to complete, the number of inverted dipoles whose negative poles face toward the upper surface of the emitter section 12b is large. As a result, as shown in FIG. 12, Coulomb repulsion causes electrons accumulated in the vicinity of the fine through hole 12c1 to begin to be emitted upward (in the positive direction of the Z-axis) through the fine through hole 12c1. Since a large number of the fine through holes 12c1 are formed in the upper electrode 12c, a large number of electrons are planarly emitted through the fine through holes 12c1.

Upon completion of positive-side polarization inversion, the element voltage Vka begins to sharply increase, and electrons are actively emitted. Subsequently, emission of electrons is completed, and the element voltage Vka reaches the positive predetermined voltage Vp. As a result, the emitter section 12b returns to its initial state (state at the point p1 in FIG. 7) shown in FIG. 6. Thus is completed description of the principle of a series of operations concerning the accumulation and the emission of electrons.

Light Emission Control—Control of Drive Voltage Vin and Collector Voltage Vc:

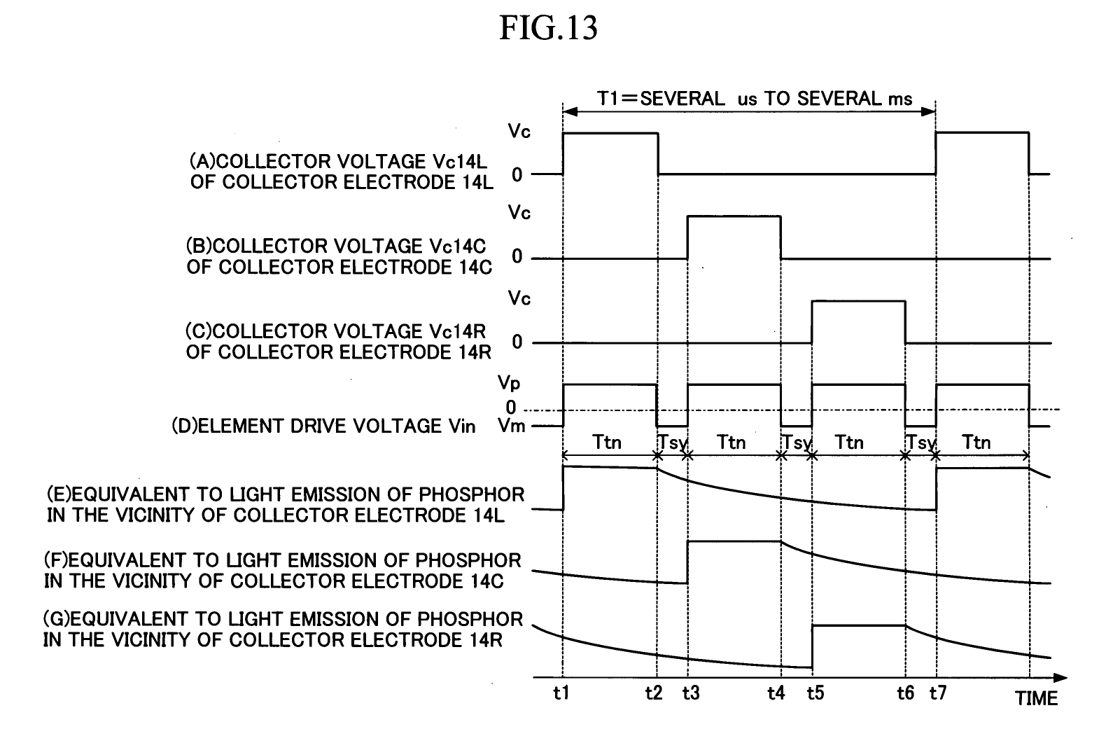

Next, an operation of the light-emitting device 10 according to the first embodiment during light emission will be described with reference to a time chart of FIG. 13. “Equivalent to light emission” appearing in (E), (F), and (G) of FIG. 13 indicates voltage (APD output voltage) which a photic-output-measuring device (avalanche photodiode (APD)) disposed above the transparent plate 13 outputs in accordance with the magnitude of photic output. This also applies to other time charts.

First, suppose that it is before time t1 and that the light-emitting device is in a state in which a large number of electrons are accumulated at an upper portion of the emitter section 12b of the electron emitter 12. When time t1 is reached, as shown in (D) of FIG. 13, the electron emission drive circuit 16 applies the electron emission voltage Vp (V) between the lower electrode 12a and the upper electrode 12c of the electron emitter 12. This causes a large number of electrons accumulated at the upper portion of the emitter section 12b to be planarly emitted through the fine through holes 12c1 of the upper electrode 12c.

At the same time (time t1), as shown in (A) of FIG. 13, the collector voltage application circuit 17 applies a constant positive collector voltage Vc (V) to the left collector electrode 14L. In other words, the collector voltage application circuit 17 changes a voltage Vc14L to be applied to the left collector electrode 14L, from 0 V to Vc V. Also, as shown in (B) and (C) of FIG. 13, the collector voltage application circuit 17 holds at 0 V the voltage Vc14C and the voltage Vc14R to be applied to the center collector electrode 14C and the right collector electrode 14R, respectively.

As shown in FIG. 1, this causes electrons emitted from the electron emitter 12 to be attracted to the left collector electrode 14L, to which the collector voltage Vc is applied. Accordingly, electrons impinge on the phosphor 15 in a region located in the vicinity of the left collector electrode 14L (a region of the phosphor 15 in contact with the left collector electrode 14L). As a result, as shown in (E) of FIG. 13, the region of the phosphor 15 on which electrons impinge because of its proximity to the left collector electrode 14L emits light (the phosphor 15 emits light from the region on which electrons impinge).

Next, when time t2 is reached after elapse of a predetermined time Ttn, as shown in (D) of FIG. 13, the electron emission drive circuit 16 applies the write voltage Vm (V) between the lower electrode 12a and the upper electrode 12c of the electron emitter 12. This halts emission of electrons and initiates accumulation of electrons at an upper portion of the emitter section 12b. Preferably, the time Ttn is set equal to or longer than the time required for the electron emitter 12 to emit electrons, and shorter than such a time that even when the region of the phosphor 15 in the vicinity of the left collector electrode 14L is subjected to impingement of electrons for the time or longer, the quantity of light emission from the region of the phosphor 15 does not increase, and energy of electrons changes to heat.

At the same time (time t2), as shown in (A) of FIG. 13, the collector voltage application circuit 17 halts application of the collector voltage Vc (V) to the left collector electrode 14L. In other words, the collector voltage application circuit 17 changes the voltage Vc14L to be applied to the left collector electrode 14L, from Vc V to 0 V.

This terminates impingement of electrons on the region of the phosphor 15 in the vicinity of the left collector electrode 14L. As a result, as shown in (E) of FIG. 13, the region of the phosphor 15 which emitted light during a period of time between time t1 and time t2 emits afterglow at and after time t2. The intensity of afterglow (quantity of light) attenuates with time.

When time t3 is reached after elapse of a predetermined time Tsy from time t2, as shown in (D) of FIG. 13, the electron emission drive circuit 16 again applies the electron emission voltage Vp (V) between the lower electrode 12a and the upper electrode 12c of the electron emitter 12. This causes a large number of electrons to again be planarly emitted through the fine through holes 12c1 of the upper electrode 12c. The time Tsy is set to time (or longer) required for the electron emitter 12 to accumulate a sufficiently large number of electrons at an upper portion of the emitter section 12b.

At the same time (time t3), as shown in (B) of FIG. 13, the collector voltage application circuit 17 applies the constant positive collector voltage Vc (V) to the center collector electrode 14C. In other words, the collector voltage application circuit 17 changes a voltage Vc14C to be applied to the center collector electrode 14C, from 0 V to Vc V. Also, as shown in (A) and (C) of FIG. 13, the collector voltage application circuit 17 holds at 0 V the voltage Vc14L and the voltage Vc14R to be applied to the left collector electrode 14L and the right collector electrode 14R, respectively.

This causes electrons emitted planarly from the electron emitter 12 in the positive direction of the Z-axis to be attracted to the center collector electrode 14C, to which the collector voltage Vc is applied. Accordingly, electrons impinge on the phosphor 15 in a region located in the vicinity of the center collector electrode 14C (a region of the phosphor 15 in contact with the center collector electrode 14C). As a result, as shown in (F) of FIG. 13, the region of the phosphor 15 on which electrons impinge emits light.

When time t4 is reached after elapse of the predetermined time Ttn from time t3, as shown in (D) of FIG. 13, the electron emission drive circuit 16 again applies the write voltage Vm (V) to the electron emitter 12. This halts emission of electrons and initiates accumulation of electrons at the upper portion of the emitter section 12b.

At the same time (time t4), as shown in (B) of FIG. 13, the collector voltage application circuit 17 halts application of the collector voltage Vc (V) to the center collector electrode 14C. In other words, the collector voltage application circuit 17 changes the voltage Vc14C to be applied to the center collector electrode 14C, from Vc V to 0 V.

This terminates impingement of electrons on the region of the phosphor 15 in the vicinity of the center collector electrode 14C. As a result, the region of the phosphor 15 which emitted light during a period of time between time t3 and time t4 emits afterglow at and after time t4. The intensity of afterglow (quantity of light) attenuates with time.

When time t5 is reached after elapse of the predetermined time Tsy from time t4, as shown in (D) of FIG. 13, the electron emission drive circuit 16 again applies the electron emission voltage Vp (V) to the electron emitter 12. This causes a large number of electrons to again be planarly emitted through the fine through holes 12c1 of the upper electrode 12c.

At the same time (time t5), as shown in (C) of FIG. 13, the collector voltage application circuit 17 applies the constant positive collector voltage Vc (V) to the right collector electrode 14R. In other words, the collector voltage application circuit 17 changes a voltage Vc14R to be applied to the right collector electrode 14R, from 0 V to Vc V. Also, as shown in (A) and (B) of FIG. 13, the collector voltage application circuit 17 holds at 0 V the voltage Vc14L and the voltage Vc14C to be applied to the left collector electrode 14L and the center collector electrode 14C, respectively.

This causes electrons emitted planarly from the electron emitter 12 in the positive direction of the Z-axis to be attracted to the right collector electrode 14R, to which the collector voltage Vc is applied. Accordingly, electrons impinge on the phosphor 15 in a region located in the vicinity of the right collector electrode 14R (a region of the phosphor 15 in contact with the right collector electrode 14R). As a result, as shown in (G) of FIG. 13, the region of the phosphor 15 on which electrons impinge emits light.

When time t6 is reached after elapse of the predetermined time Ttn from time t5, as shown in (D) of FIG. 13, the electron emission drive circuit 16 again applies the write voltage Vm (V) to the electron emitter 12. This halts emission of electrons and initiates accumulation of electrons at an upper portion of the emitter section 12b.

At the same time (time t6), as shown in (C) of FIG. 13, the collector voltage application circuit 17 halts application of the collector voltage Vc (V) to the right collector electrode 14R. In other words, the collector voltage application circuit 17 changes the voltage Vc14R to be applied to the right collector electrode 14R, from Vc V to 0 V.

This terminates impingement of electrons on the region of the phosphor 15 in the vicinity of the right collector electrode 14R. As a result, the region of the phosphor 15 which emitted light during a period of time between time t5 and time t6 emits afterglow at and after time t6. The intensity of afterglow (quantity of light) attenuates with time. Subsequently, when time t7 is reached after elapse of the predetermined time Tsy from time t6, the same operation at and after time t1 is repeated.

As described above, with the light-emitting device 10 according to the first embodiment, during a period of time when the collector voltage Vc is applied to one of the collector electrodes 14 to thereby subject the collector electrode 14 to impingement of electrons; for example, during a period of time between time t5 and time t6, a region of the phosphor 15 in the vicinity of the right collector electrode 14R is subjected to impingement of electrons and emits light, and the left collector electrode 14L and the center collector electrode 14C emit afterglow. In this period of time, the intensity of afterglow from the center collector electrode 14C is considerably high, since only a short time has elapsed from start of attenuation (from time t4). Meanwhile, the intensity of afterglow from the left collector electrode 14L is considerably low, since a long time has elapsed after start of attenuation (from time t2); however, the intensity is not completely “0.” As a result, since the three collector electrodes 14L, 14C, and 14R all emit light, the light-emitting device 10 can emit a large quantity of light while maintaining even emission of light (low degree of uneven brightness).

Similarly, for example, during a period of time between time t4 and time t5 when none of the collector electrodes 14 are subjected to impingement of electrons, the three collector electrodes 14L, 14C, and 14R emit afterglow of respective intensities. Therefore, this also ensures a large quantity of light and even emission of light (low degree of uneven brightness).

As described above, in the light-emitting device 10 according to the first embodiment of the present invention, the collector voltage Vc is applied to a plurality of collector electrodes (14L, 14C, and 14R) in respective different periods of time. Accordingly, electrons impinge on the phosphor 15 in a region in the vicinity of the collector electrode to which the collector voltage Vc is applied, and the region of the phosphor 15 emits light. The other region of the phosphor 15 emits afterglow. Accordingly, the light-emitting device 10 can utilize light emission of the phosphor 15 effected through impingement of electrons thereon and afterglow of the phosphor 15. Thus, the device 10 can emit a large quantity of light at high efficiency without impingement of excess electrons on the phosphor 15 (in other words, without waste of power to be applied to the electron emitters).

Second Embodiment:

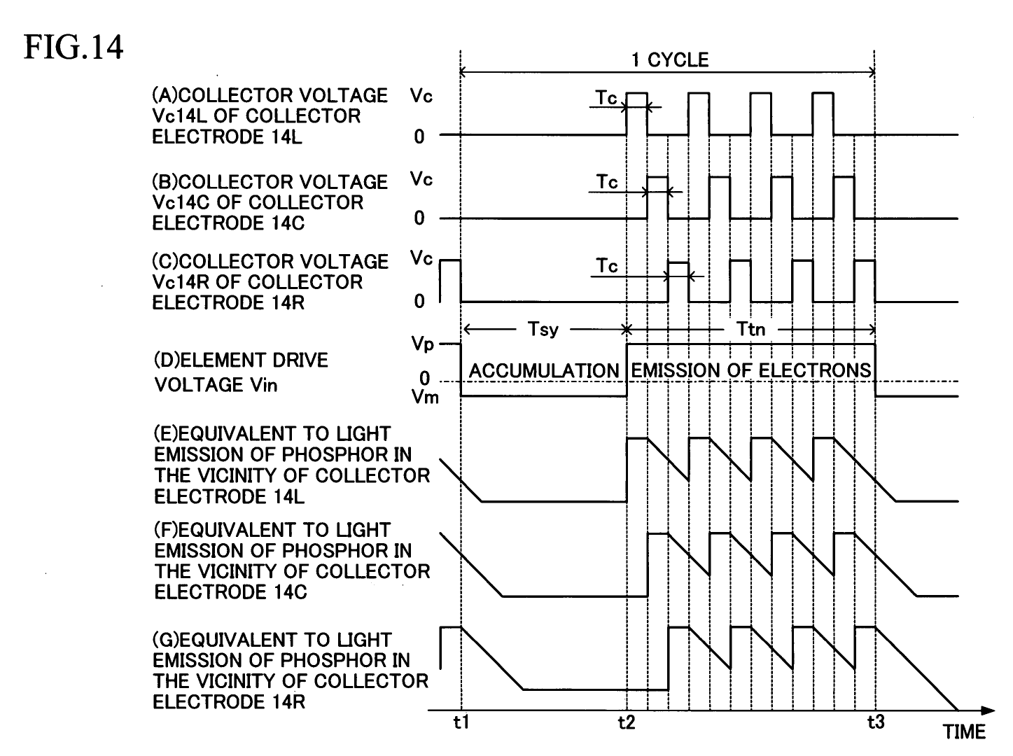

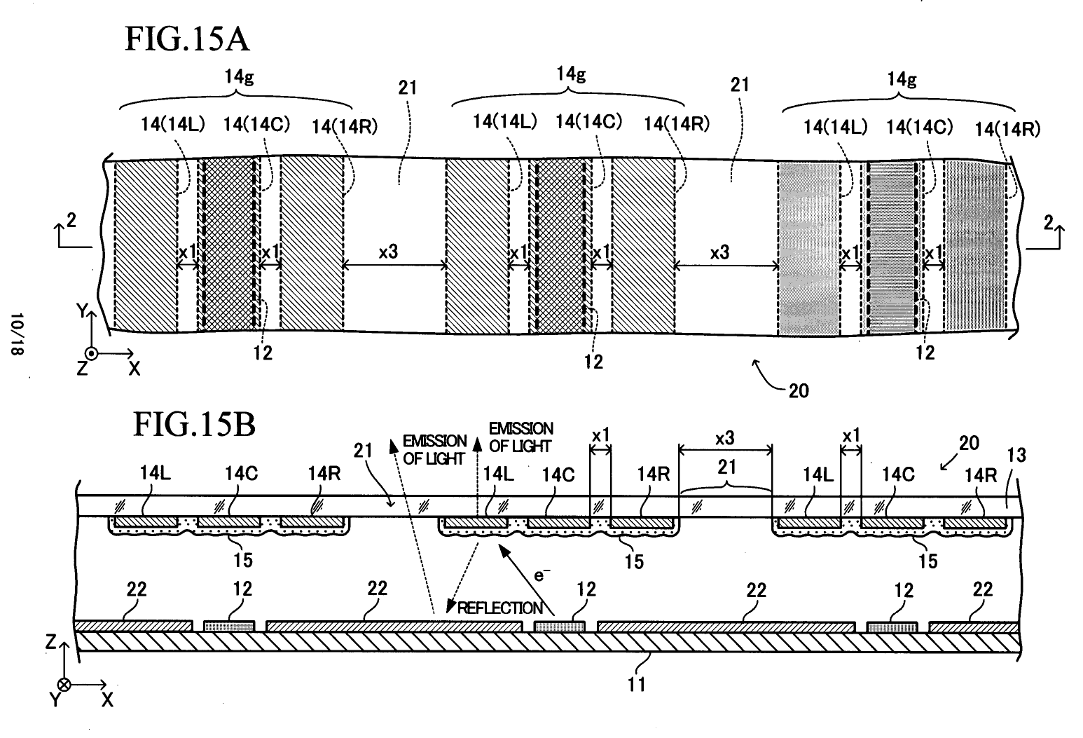

Next, a light-emitting device according to a second embodiment of the present invention will be described. The light-emitting device has the same configuration as that of the light-emitting device 10 according to the first embodiment except for an application method for the collector voltage Vc and the drive voltage Vin (write voltage Vm and electron emission voltage Vp). The light-emitting device will be described with reference to a time chart shown in FIG. 14 while the description is focused on the above point of difference.

As shown in (D) of FIG. 14, during a predetermined period of time (write period) Tsy between time t1 and time t2, the electron emission drive circuit 16 of the light-emitting device applies the write voltage Vm (V) between the lower electrode 12a and the upper electrode 12c of the electron emitter 12. Accordingly, during this period of time, emission of electrons is halted, and electrons are accumulated at the upper portion of the emitter section 12b.

Further, during a predetermined period of time (electron emission period, light ON period) Ttn between time t2 and time t3, the electron emission drive circuit 16 applies the electron emission voltage Vp (V) between the lower electrode 12a and the upper electrode 12c of the electron emitter 12. Accordingly, during this period of time, a large number of electrons are planarly emitted through the fine through hole 12c1 of the upper electrode 12c.

As shown in (A), (B), and (C) of FIG. 14, during the predetermined period Tsy between time t1 and time t2, the collector voltage application circuit 17 does not apply the collector voltage Vc to any of the collector electrodes 14L, 14C, and 14R.

Further, during the electron emission period Ttn between time t2 and time t3, the collector voltage application circuit 17 applies the collector voltage Vc to each of the collector electrodes every elapse of a predetermined time Tc in a predetermined sequence; for example, in the sequence of the left collector electrode 14L, the center collector electrode 14C, the right collector electrode 14R, and again the left collector electrode 14L, . . . . In other words, the collector voltage application circuit 17 repeats an operation of applying the pulse-like collector voltage Vc to each of the plurality of collector electrodes (14L, 14C, and 14R) in a predetermined sequence (herein, in the sequence of 14L, 14C, and 14R).

During the period Ttn between time t2 and time t3 when electrons are emitted from the electron emitter 12, this causes the electrons to be attracted to the collector electrodes (14L, 14C, and 14R) in a predetermined sequence; i.e., in the sequence of the left collector electrode 14L, the center collector electrode 14C, the right collector electrode 14R, and again the left collector electrode 14L . . . . As a result, as shown in (E) to (G) of FIG. 14, a region of the phosphor 15 located in the vicinity of the collector electrode which attracts electrons emits light through impingement of electrons thereon. Regions of the phosphor 15 located in the vicinity of the collector electrodes to which the collector voltage Vc is not applied emit afterglow, which attenuates with time.

In the light-emitting device, during the period Ttn between time t2 and time t3, the pulse-like collector voltage Vc is applied to each of the collector electrodes only four times. In the light-emitting device, the period between time t1 and time t3 is taken as one cycle. Accordingly, at and after time t3, the same operation as that at and after time t1 is repeated.

As described above, the light-emitting device according to the second embodiment can efficiently emit light as in the case of the light-emitting device 10 of the first embodiment. Further, the collector voltage application circuit 17 of the second embodiment applies the collector voltage Vc at least once to each of a plurality of collector electrodes (14L, 14C, and 14R) during a period of time between start and end of application of the electron emission voltage Vp by the electron emission drive circuit 16 (e.g., during a period between time t2 and time t3).

Accordingly, a single continuous emission of electrons from the electron emitter 12 can cause the phosphor 15 to emit light at least once in all regions located in the vicinity of the corresponding collector electrodes. In other words, while drive energy for the electron emitter associated with an operation ranging from accumulation of electrons to emission of electrons is minimized, light can be emitted evenly, highly efficiently, and over as wide range as possible.

Third Embodiment:

Next, a light-emitting device 20 according to a third embodiment of the present invention will be described with reference to FIGS. 15A and 15B. FIG. 15A is a fragmentary plan view of the light-emitting device 20. FIG. 15B is a fragmentary, sectional view of the light-emitting device 20 cut by a plane extending along line 2-2 of FIG. 15A. A group (one set) of three collector electrodes consisting of the left collector electrode 14L, the center collector electrode 14C, and the right collector electrode 14R, which are adjacent to each other and apart from each other by the aforementioned distance x1 and collect (attract) electrons emitted from a certain electron emitter 12, is called a collector electrode group 14g.

The light-emitting device 20 differs from the light-emitting device 10 of the first embodiment in that a light transmission portion (opening portion) 21 is formed between one collector electrode group 14g and adjacent another collector electrode group 14g and that a plurality of reflection plates (or scattering plates) 22 are formed on the upper surface of the substrate 11. Accordingly, the light-emitting device 20 will be described while the description is focused on the above point of difference.

The light transmission portion 21 is a portion of the transparent plate 13 located between the right collector electrode 14R of one collector electrode group 14g and the left collector electrode 14L of adjacent another collector electrode group 14g located in the positive direction of the X-axis (rightward). Nothing but un-illustrated common leads to collector electrodes are formed on the lower surface of the portion of the transparent plate 13. A width x3 of the light transmission portion 21 along the direction of the X-axis is greater than the aforementioned distance x2.

The reflection plate (or scattering plate) 22 has a thickness similar to that of the electron emitter 12. The reflection plate (or scattering plate) 22 is formed on the upper surface of the substrate 11 between one electron emitter 12 and adjacent another electron emitter 12 in such a manner as to face the collector electrode groups 14g and the light transmission portion 21 (i.e., to face the lower surface of the transparent plate 13). The width (length) of the reflection plate (or scattering plate) 22 along the direction of the X-axis is slightly smaller than the distance between two adjacent electron emitters 12.

In the light-emitting device 20, as indicated by the arrow of the broken line of FIG. 15B, the reflection plate (or scattering plate) 22 reflects light which the phosphor 15 emits toward the interior of the light-emitting device 20 (light which, because of scattering, travels while having a component along the negative direction of the Z-axis). Light reflected by the reflection plate (or scattering plate) 22 passes through the light transmission portion 21 and travels above the light-emitting device 20.

Accordingly, the light-emitting device 20 can emit not only light which passes through the collector electrodes 14 (14L, 14C, and 14R) and travels thereabove but also light which, because of scattering, travels toward the interior thereof and is then reflected by the reflection plate (or scattering plate) 22 to thereby travel thereabove. Thus, the light-emitting device 20 can emit a larger quantity of light with lower power consumption.

First Modified Embodiment of Third Embodiment:

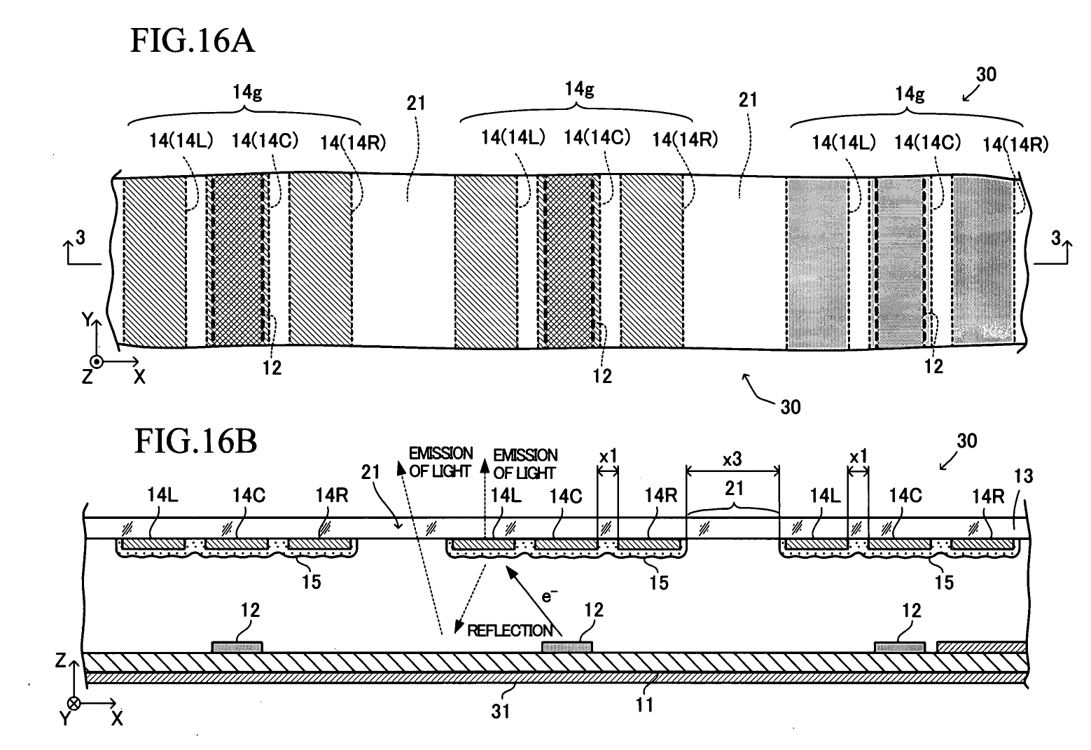

As shown in FIGS. 16A and 16B, a light-emitting device 30 according to a first modified embodiment of the third embodiment differs from the light-emitting device 20 only in that a reflection plate (or scattering plate) 31 is disposed on the lower surface of the substrate 11. As in the case of the light-emitting device 20, the light-emitting device 30 can emit light which, because of scattering, travels toward the interior thereof and is then reflected by the reflection plate (or scattering plate) 31 to thereby travel thereabove. Thus, the light-emitting device 30 can also emit a larger quantity of light with lower power consumption. Desirably, in the light-emitting device 30, the substrate 11 is formed so as to exhibit good light transmissivity.

Second Modified Embodiment of Third Embodiment:

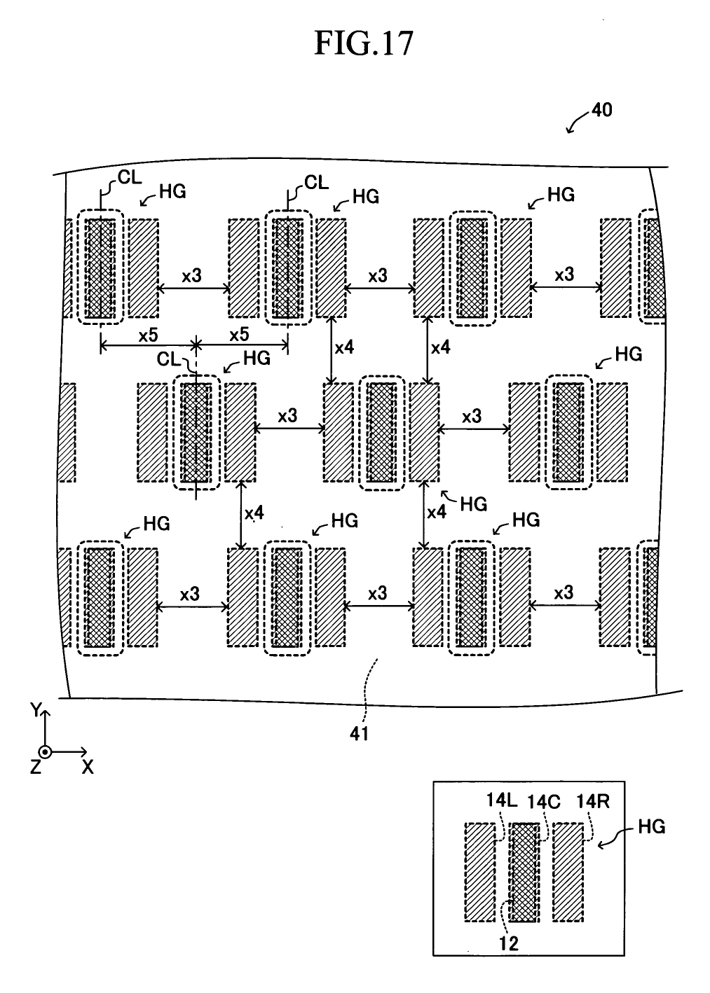

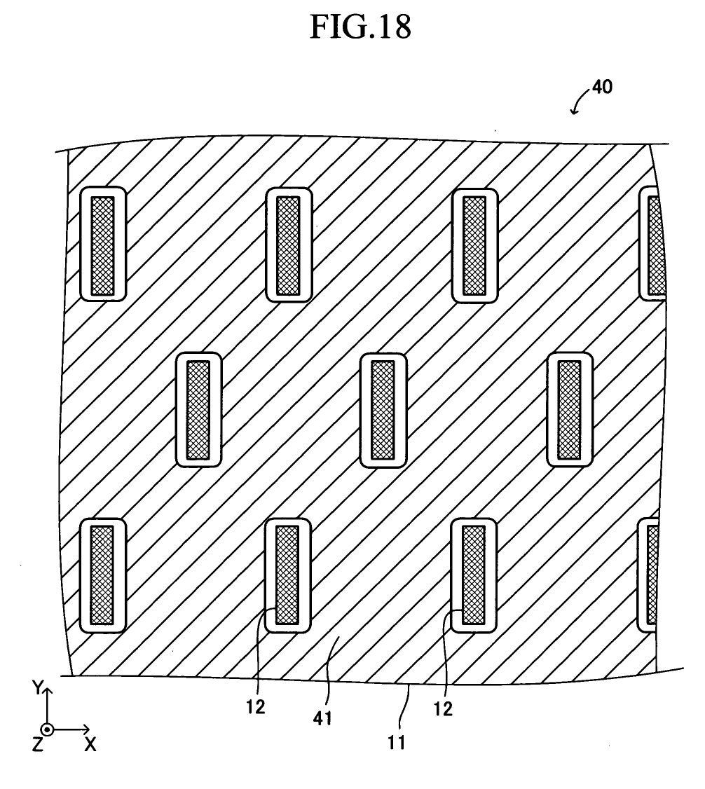

Next, a light-emitting device 40 according to a second modified embodiment of the third embodiment will be described with reference to FIGS. 17 and 18. FIG. 17 is a fragmentary plan view of the light-emitting device 40. FIG. 18 is a fragmentary plan view of the electron emitters 12 and a reflection plate (scattering plate) 41.

As shown in FIG. 17, the light-emitting device 40 includes a plurality of light emitter groups HG each consisting of three collector electrodes 14 (14L, 14C, and 14R) and one electron emitter 12. The plurality of light emitter groups HG are arranged in a so-called “staggered” fashion.

Specifically, one light emitter group HG is disposed a distance x3 apart from adjacent another light emitter group HG located adjacently in the direction of the X-axis. Further, one light emitter group HG is disposed a distance x4 apart from adjacent another light emitter group HG located adjacently in the direction of the Y-axis. The distance x4 is equivalent to the distance x3. Additionally, a center axis CL extending along the direction of the Y-axis of one light emitter group HG is located a distance x5 apart from a center axis CL of adjacent another light emitter group HG located adjacently in the direction of the Y-axis. Nothing but un-illustrated common leads to the collector electrodes are formed on the lower surface of a portion of a transparent plate between one light emitter group HG and another light emitter group HG. Thus, the light-emitting device 40 has light transmission portions in the direction of the X-axis and the direction of the Y-axis.

As shown in FIG. 18, the reflection plate (or scattering plate) 41 is formed on the entire upper surface of the substrate 11 in such a manner as to surround each of the electron emitters 12.

As a result, the light-emitting device 40 can emit, through a large number of light transmission portions, light which, because of scattering, travels toward the interior thereof and is then reflected by the reflection plate (or scattering plate) 41 to thereby travel thereabove. Thus, the light-emitting device 40 can also emit a large quantity of light with lower power consumption.

As described above, the third embodiment and the modified embodiments thereof include a plurality of the electron emitters 12. The embodiments further include the sheet-like transparent plate 13 having a lower surface in opposition to the electron-emitting sections (upper electrodes 12c) of the electron emitters 12 and in parallel with planes of the electron-emitting sections (upper surfaces of the upper electrodes 12), and the reflection plate or the scattering plate (22, 31, or 41).

The plurality of collector electrodes (14L, 14C, and 14R), and the phosphor 15 are formed on the lower surface of the transparent plate 13.

The reflection plate or the scattering plate (22, 31, or 41) is disposed at a position avoiding hindrance to travel of electrons that are emitted from the electron emitters 12 and are directed toward the plurality of collector electrodes (14L, 14C, and 14R), and is disposed in opposition to the lower surface of the transparent plate 13 and in opposition to the collector electrodes (14L, 14C, and 14R).

Further, the transparent plate 13 has the light transmission portion 21 formed at a position located between an end collector electrode (e.g., the collector electrode 14R) of one group of collector electrodes attracting electrons emitted from one of the plurality of electron emitters 12 and an end collector electrode (e.g., the collector electrode 14L located adjacently in the positive direction of the X-axis to the collector electrode 14R), adjacent to the first-mentioned end collector electrode, of another group of collector electrodes attracting electrons emitted from another one (another electron emitter 12 adjacent to the former one electron emitter 12) of the plurality of electron emitters 12, the light transmission portion 21 allowing transmission therethrough of light reflected from the reflection plate or the scattering plate (22, 31, or 41).

As a result, light scattered and directed toward the side where the electron emitters 12 are formed (light which travels while having a component along the negative direction of the Z-axis) can be reflected by the reflection plate or the scattering plate (22, 31, or 41) so as to be directed again toward the transparent plate 13 (so as to be changed into light which travels while having a component along the positive direction of the Z-axis), and so as to be emitted to the exterior of the light-emitting device (20, 30, or 40) through the light transmission portion 21. Thus, the light-emitting devices (20, 30, and 40) can emit a larger quantity of light with smaller power consumption.

Fourth Embodiment:

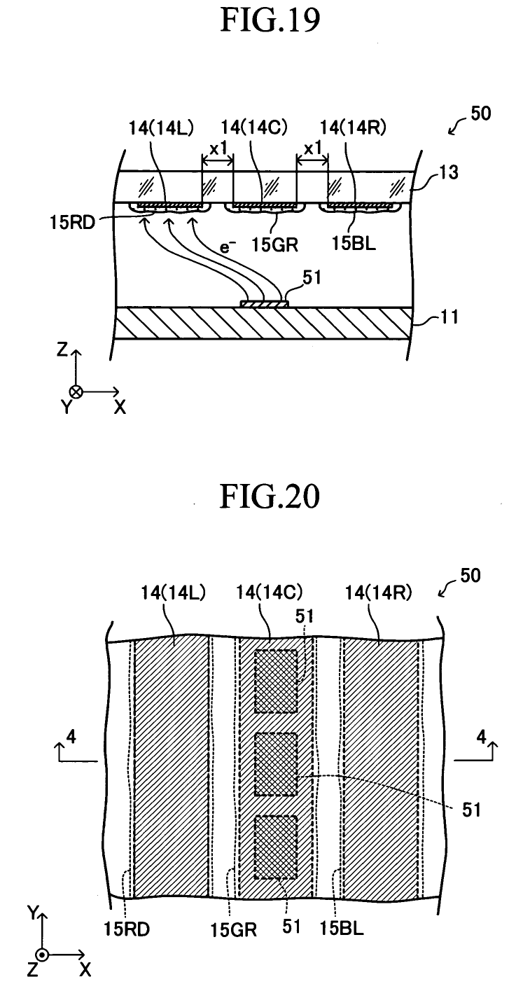

Next, a light-emitting device 50 according to a fourth embodiment of the present invention will be described, with reference to FIGS. 19 and 20. FIG. 19 is a fragmentary, sectional view of the light-emitting device 50. FIG. 20 is a fragmentary plan view of the light-emitting device 50. FIG. 20 is a sectional view of the light-emitting device 50 cut by a plane extending along line 4-4 of FIG. 19. Like component members in the light-emitting devices 10 and 50 of the first and fourth embodiments are denoted by like reference numerals, and description thereof is omitted from the description given below.

The light-emitting device 50 can form pixels of a color display unit. In the light-emitting device 50, a left collector electrode 14L is covered with a red phosphor 15RD, which emits red light through impingement of electrons thereon (irradiation with electrons). A center collector electrode 14C is covered with a green phosphor 15GR, which emits green light through impingement of electrons thereon. A right collector electrode 14R is covered with a blue phosphor 15BL, which emits blue light through impingement of electrons thereon. An electron emitter 51 which replaces the electron emitter 12 used in the light-emitting device 10 is shorter in length along the direction of the Y-axis than the electron emitter 12 and has a size corresponding to a pixel.

The red phosphor 15RD is of, for example, SrTiO₃:Pr, Y₂O₃:Eu, or Y₂O₂S:Eu. The green phosphor 15GR is of, for example, Zn(Ca, Al)₂O₄:Mn, Y₃(Al, Ga)₅O₁₂:Tb, or ZnS:Cu, Al. The blue phosphor 15BL is of, for example, Y₂SiO₅:Ce, ZnGa₂O₄, or ZnS:Ag, Cl.

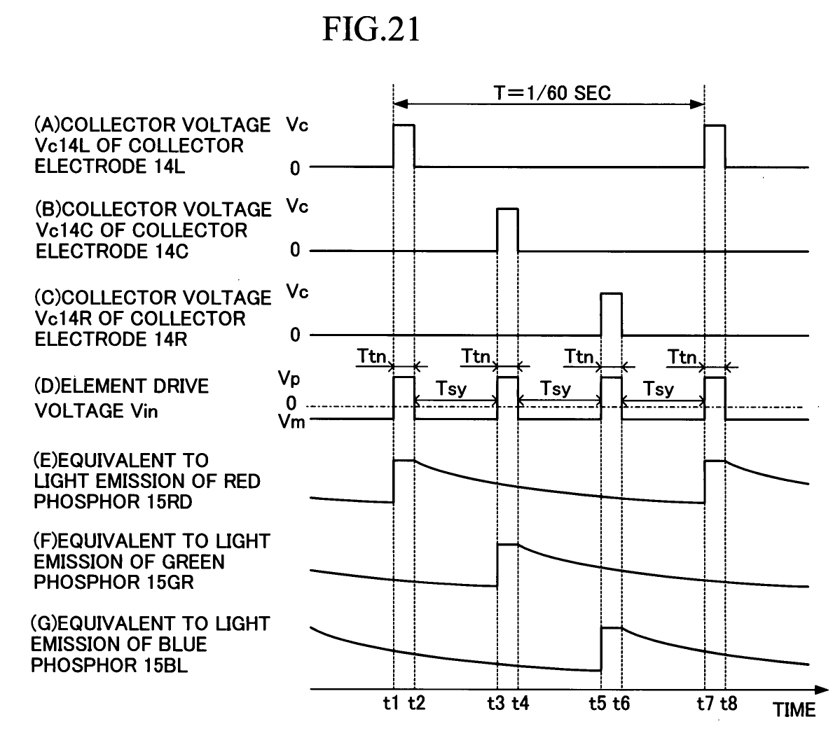

Next, an operation of the light-emitting device 50 according to the fourth embodiment during light emission will be described with reference to a time chart of FIG. 21.

As shown in (D) of FIG. 21, the electron emission drive circuit 16 of the light-emitting device 50 alternately applies the electron emission voltage Vp (V) and the write voltage Vm (V) between the lower electrode and the upper electrode of the electron emitter 51. The electron emission voltage Vp (V) is applied only for a predetermined period of time Ttn. During the period Ttn, a large number of electrons accumulated in the emitter section are planarly emitted through fine through holes of the upper electrode. The write voltage Vm (V) is applied only for a predetermined period of time Tsy. During the period Tsy, emission of electrons is halted, and electrons are accumulated at an upper portion of the emitter section. A total period of the period Ttn and the period Tsy is ⅓ of 1/60 sec. In other words, the light-emitting device 50 emits electrons from the light emitter 51 three times in one cycle T (working frequency=60 Hz), which is 1/60 sec.

Meanwhile, as shown in (A) of FIG. 21, the collector voltage application circuit 17 of the light-emitting device 50 applies the collector voltage Vc only to the left collector electrode 14L during the period Ttn between time t1 and time t2. As shown in (B) of FIG. 21, the collector voltage application circuit 17 applies the collector voltage Vc only to the center collector electrode 14C during the period Ttn between t3 and time t4. Further, as shown in (C) of FIG. 21, the collector voltage application circuit 17 applies the collector voltage Vc only to the right collector electrode 14R during the period Ttn between time t5 and time t6.

As a result, the red phosphor 15RD, which is formed in such a manner as to cover the left collector electrode 14L, emits red light through impingement of electrons thereon during the period between time t1 and time t2 and emits, during the remaining period, red afterglow whose intensity attenuates with time. Similarly, the green phosphor 15GR, which is formed in such a manner as to cover the center collector electrode 14C, emits green light through impingement of electrons thereon during the period between time t3 and time t4 and emits, during the remaining period, green afterglow whose intensity attenuates with time. The blue phosphor 15BL, which is formed in such a manner as to cover the right collector electrode 14R, emits blue light through impingement of electrons thereon during the period between time t5 and time t6 and emits, during the remaining period, blue afterglow whose intensity attenuates with time. Subsequently, the light-emitting device 50 repeats the operation every 1/60 sec.

As described above, in the light-emitting device 50, a plurality of the phosphors are provided, and the plurality of phosphors (15RD, 15GR, and 15BL) are disposed in the vicinity of the corresponding collector electrodes (14L, 14C, and 14R) and emit light of different colors. Thus, the light-emitting device 10 is a device which emits light of colors. The phosphors (15RD, 15GR, and 15BL) generate light of red, green, and blue, which are three primary colors of light. Accordingly, the light-emitting device 50 can be used for displaying an image on a color display or the like.

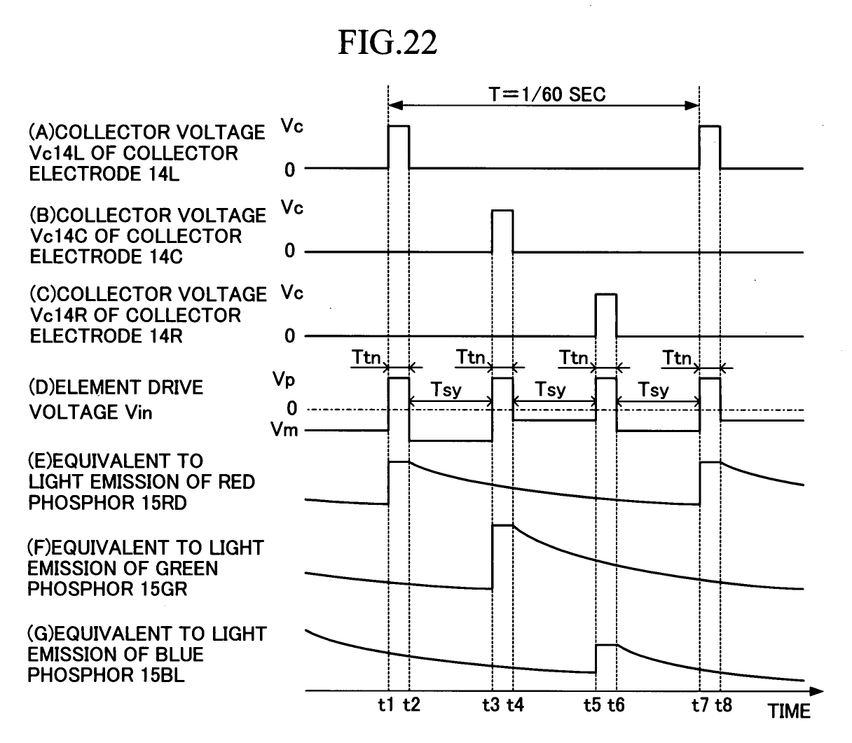

The electron emitter 51 is such that, the greater the absolute value of the write voltage Vm (V) during the write period Tsy, a larger number of electrons are accumulated in the emitter section. As a result, during the electron emission period Ttn subsequent to the write period Tsy, the electron emitter 51 can emit a larger number of electrons. Accordingly, by means of varying the absolute value of the write voltage Vm (V) during the write period Tsy, the individual phosphors are subjected to impingement of electrons in different quantities; in other words, the quantity of light emission of the individual phosphors can be varied. Thus, in a display in which the light-emitting devices 50 are in a matrix array, the absolute value of the write voltage Vm (V) during the write period Tsy is varied with respect to individual colors for each of pixels of an image to be displayed so as to emit light of the colors in respective intensities required for display of the image, whereby a required color image can be displayed. FIG. 22 shows voltage waveforms relative to green, red, and blue in the case where brightness of colors is lowered in the sequence of green, red, and blue.

The above-described light-emitting device 50 uses a working frequency of 60 Hz. However, the working frequency may be modified to 50 Hz, 72 Hz, integral multiples thereof, or the like as required by an image to be displayed.

Example Materials and Example Manufacturing Methods for Component Members:

Next, example materials and example manufacturing methods for component members of the above-described electron emitters 12 and 51 will be described.

Substrate:

The substrate may be formed from a material whose main component is aluminum oxide, or a material whose main component is a mixture of aluminum oxide and zirconium oxide.

Lower Electrode:

As mentioned previously, an electrically conductive substance (e.g., a metal conductor, such as platinum, molybdenum, tungsten, gold, silver, copper, aluminum, nickel, or chromium) is used to form the lower electrode. Substances preferably used to form the lower electrode are listed below.
(1) Conductors (e.g., simple metals or alloys) resistant to high-temperature oxidizing atmosphere:

Example: noble metals having high melting point, such as platinum, iridium, palladium, rhodium, and molybdenum.

Example: metals whose main component is silver-palladium, silver-platinum, platinum-palladium, or a like alloy.
(2) Mixtures of an insulating ceramic material and a simple metal, resistant to high-temperature oxidizing atmosphere:

Example: cermet material of platinum and a ceramic material.
(3) Mixtures of an insulating ceramic material and an alloy, resistant to high-temperature oxidizing atmosphere.
(4) Carbon or graphite materials.

Among these materials, platinum or a material whose main component is a platinum alloy is very preferred. When a ceramic material is to be added to an electrode material, a preferred content thereof is about 5 vol % to 30 vol %. Materials which are used to form the upper electrode as will be described later may be used to form the lower electrode. A thick-film deposition process is preferably applied to formation of the lower electrode. The thickness of the lower electrode is preferably 20 μm or less, more preferably 5 μm or less.

Emitter Section:

A dielectric material having a relatively high dielectric constant (e.g., a dielectric constant of 1,000 or higher) can be employed to form the emitter section. Substances preferably used to form the emitter section are listed below:
(1) Barium titanate, lead zirconate, magnesium lead niobate, nickel lead niobate, zinc lead niobate, manganese lead niobate, magnesium lead tantalate, nickel lead tantalate, antimony lead stannate, lead titanate, magnesium lead tungstate, and cobalt lead niobate.
(2) Ceramic materials which contain in combination the substances mentioned above in (1).
(3) Ceramic materials mentioned above in (2) which further contain singly oxides of lanthanum, calcium, strontium, molybdenum, tungsten, barium, niobium, zinc, nickel, and manganese. Ceramic materials mentioned above in (2) which further contain in combination the oxides. Ceramic materials mentioned above in (2) which further contain singly or in combination the oxides, as well as other compound(s), as appropriate.
(4) Substances whose main components contain singly or in combination the substances mentioned above in (1) in an amount of 50% or more.

Notably, for example, in a 2-component material of magnesium lead niobate (PMN) and lead titanate (PT) “nPMN-mPT” (n, m: mole ratio), increase of the mole ratio of PMN lowers the Curie point and can increase dielectric constant at room temperature. Particularly, an nPMN-mPT in which n=0.85 to 1.0 and m=1.0−n is very preferred as a material for the emitter section, since a dielectric constant of 3,000 or more is obtained. For example, an nPMN-mPT in which n=0.91 and m=0.09 has a dielectric constant of 15,000 at room temperature. An nPMN-mPT in which n=0.95 and m=0.05 has a dielectric constant of 20,000 at room temperature.

Also, for example, in a 3-component material of magnesium lead niobate (PMN), lead titanate (PT), and lead zirconate (PZ) “PMN-PT-PZ,” increase of the mole ratio of PMN can increase dielectric constant. Further, in the 3-component material, the employment of a composition near the morphotropic phase boundary (MPB) between the tetragonal system and the pseudo-cubic system or between the tetragonal system and the rhombohedral system can increase dielectric constant.

For example, with PMN:PT:PZ=0.375:0.375:0.25, a dielectric constant of 5,500 is obtained, and with PMN:PT:PZ=0.5:0.375:0.125, a dielectric constant of 4,500 is obtained. Thus, a PMN-PT-PZ having such a composition is particularly preferred as a material for the emitter section.

Further preferably, permittivity is enhanced by means of adding platinum or a like metal to these dielectric materials within such a range of amount as not to impair the insulating property. In this case, for example, platinum may be added to the dielectric material in an amount of 20% by weight.

A piezoelectric/electrostrictive layer, an antiferroelectric layer, or the like can be used to form the emitter section. In the case where a piezoelectric/electrostrictive layer is used to form the emitter section, the piezoelectric/electrostrictive layer is formed from, for example, a ceramic material which contains singly or in combination lead zirconate, magnesium lead niobate, nickel lead niobate, zinc lead niobate, manganese lead niobate, magnesium lead tantalate, nickel lead tantalate, antimony lead stannate, lead titanate, barium titanate, magnesium lead tungstate, and cobalt lead niobate.

Needless to say, ceramic materials whose main components contain the above compounds singly or in combination in an amount of 50% by weight or more can be used to form the emitter section. Among the above-mentioned ceramic materials, a ceramic material which contains lead zirconate is most frequently used to form a piezoelectric/electrostrictive layer, which in turn is used to form the emitter section.

In the case where a ceramic material is used to form the piezoelectric/electrostrictive layer, the ceramic material may be any of the above ceramic materials which further contains singly or in combination oxides of lanthanum, calcium, strontium, molybdenum, tungsten, barium, niobium, zinc, nickel, and manganese, as well as other compound(s), as appropriate. The ceramic material may be any of the above ceramic materials which further contains singly or in combination SiO₂, CeO₂, and Pb₅Ge₃O₁₁. Specifically, the ceramic material is preferably a PT-PZ-PMN piezoelectric material to which 0.2 wt % SiO₂, 0.1 wt % CeO₂, or 1 wt % to 2 wt % Pb₅Ge₃O₁₁ is added.

More specifically, preferably, for example, the ceramic material contains a main component composed of magnesium lead niobate, lead zirconate, and lead titanate and also contains lanthanum and strontium.

The piezoelectric/electrostrictive layer may be dense or porous. When a porous piezoelectric/electrostrictive layer is used, its porosity is preferably 40% or less.

When an antiferroelectric layer is used to form the emitter section, desirably, the antiferroelectric layer is formed from a material which contains lead zirconate as a main component, a material whose main component is composed of lead zirconate and lead stannate, a lead zirconate material to which lanthanum oxide is added, or a lead-zirconate-lead-stannate material to which lead zirconate or lead niobate is added.

The antiferroelectric layer may be porous. When a porous antiferroelectric layer is used, its porosity is preferably 30% or less.

Use of strontium tantalate bismuthate (SrBi₂Ta₂O₉) to form the emitter section is preferred, since polarization inversion fatigue is low. Such materials having low polarization inversion fatigue are layered ferroelectric compounds and represented by the general formula (BiO₂)²⁺(Aₘ₋₁BₘO₃ₘ₊₁)²⁻, wherein ions of metal A are, for example, Ca²⁺, Sr²⁺, Ba²⁺, Pb²⁺, Bi³⁺, La³⁺, and ions of metal B are, for example, Ti⁴⁺, Ta⁵⁺, and Nb⁵⁺. Further, barium titanate piezoelectric ceramics, lead zirconate piezoelectric ceramics, and PZT piezoelectric ceramics can be rendered semiconducting by adding additives. This enables electric field concentration in the vicinity of the interface between the emitter section and the upper electrode, which contributes to emission of electrons, through uneven electric field distribution within the emitter section.

By means of mixing a glass component, such as lead borosilicate glass, or other low-melting-point compound (e.g., bismuth oxide), into piezoelectric/electrostrictive/antiferroelectric ceramics, firing temperature for the emitter section can be lowered.

When a piezoelectric/electrostrictive/antiferroelectric ceramic is used to form the emitter section, the emitter section may assume the form of a molded sheet, a laminated sheet, or a laminate composed of a substrate and the sheet laminated thereon or bonded thereto.

By means of using a lead-free material to form the emitter section, high melting point or high transpiration temperature is imparted to the emitter section, whereby the emitter section becomes unlikely to be damaged by electrons or ions impinging thereon.

A thick-film deposition process or a thin-film deposition process can be used to form the emitter section. Examples of such a thick-film deposition process include a screen printing process, a dipping process, an application process, an electrophoresing process, and an aerosol deposition process. Examples of such a thin-film deposition process include an ion beam process, a sputtering process, a vacuum vapor deposition process, an ion plating process, a chemical vapor deposition (CVD) process, and a plating process. Particularly, a film can be formed at a low temperature of 700° C. or 600° C. or lower by the following process: a piezoelectric/electrostrictive material powder is formed into the shape of the emitter section, followed by impregnation with low-melting-point glass or sol particles.

Upper Electrode:

An organometallic paste (e.g., a platinum resinate paste), which provides a thin film after firing, is used to form the upper electrode. An oxide electrode material which suppresses polarization inversion fatigue, or a material prepared by mixing an oxide electrode material which suppresses polarization inversion fatigue, into a platinum resinate paste is preferably used to form the upper electrode. Examples of an oxide electrode material which suppresses polarization inversion fatigue include ruthenium oxide (RuO₂), iridium oxide (IrO₂), strontium ruthenate (SrRuO₃), La₁₋ₓSrₓCoO₃ (e.g., x=0.3 or 0.5), La₁₋ₓCaₓMnO₃ (e.g., x=0.2), and La₁₋ₓCaₓMn_{1-y}Co_{y}O₃ (e.g., x=0.2, y=0.05).

Preferably, an aggregate of a scale-like substance (e.g., graphite) or an aggregate of an electrically conductive substance containing a scale-like substance is used to form the upper electrode. An aggregate of such a substance has, in itself, portions at which scales are apart from one another, so that such portions can be used as the previously mentioned fine through holes of the upper electrode without subjection to a thermal processing such as firing. Alternatively, the upper electrode may be formed as follows: an organic resin layer and a metal thin-film are sequentially formed in layers on the emitter section, and the resultant laminate is fired so as to burn out the organic resin for forming fine through holes in the metal thin-film.

The upper electrode can be formed by an ordinary thick-film deposition process or an ordinary thin-film deposition process while using any of the above-mentioned materials. Examples of such a thick-film deposition process include a screen printing process, a spraying process, a coating process, a dipping process, an application process, and an electrophoresing process. Examples of such a thin-film deposition process include a sputtering process, an ion beam process, a vacuum vapor deposition process, an ion plating process, a chemical vapor deposition (CVD) process, and a plating process.

As described above, a light-emitting device according to any of the embodiments of the present invention includes an electron emitter (12 or 51) for accumulating therein a large number of electrons upon application of a predetermined write voltage Vm thereto and for planarly emitting the accumulated large number of electrons from a planar electron-emitting section (upper electrode) thereof upon application of a predetermined electron emission voltage Vp thereto; a plurality of collector electrodes (14 or 14′) disposed in opposition to the electron-emitting section (disposed in opposition to the electron-emitting section and in parallel with a plane of the electron-emitting section) and adapted to attract, upon application of a predetermined collector voltage Vc thereto, electrons emitted from the electron emitter; a phosphor(s) (15, 15RD, 15GR, or 15BL) disposed in the vicinity of the plurality of collector electrodes (14 or 14′) and emitting light through impingement of electrons thereon; an electron emission drive circuit (16) for alternately applying the write voltage and the electron emission voltage to the electron emitter; and a collector voltage application circuit (17) for applying the collector voltage to the plurality of collector electrodes in respective different periods of time when the electron emitter is emitting electrons.

Accordingly, the collector voltage Vc is applied to the plurality of collector electrodes in respective different periods of time. Thus, electrons impinge on the phosphor in a region located in the vicinity of the collector electrode to which the collector voltage Vc is applied, and the region of the phosphor emits light. Even after halt of application of the collector voltage Vc thereto, the region of the phosphor emits afterglow. Thus, since the light-emitting device of the present invention can utilize light emitted from a region of the phosphor on which electrons impinge, and afterglow emitted from another region of the phosphor, a large quantity of light can be emitted without impingement of excess electrons on the phosphor (in other words, without waste of power to be applied to the electron emitter).

In the above-described embodiments, during application of the collector voltage Vc to one of the plurality of collector electrodes (14L, 14C, and 14R) associated with a certain electron emitter 12 for subjection to impingement of electrons from the electron emitter 12, the collector voltage application circuit 17 does not apply the collector voltage Vc to the remaining collector electrodes.

According to this feature, electrons emitted from the electron emitter can be reliably attracted to any of the collector electrodes. Accordingly, a region of the phosphor located in the vicinity of a collector electrode attracting electrons can reliably emit light.

Further, the collector voltage application circuit 17 repeats an operation of applying the collector voltage Vc to each of the plurality of collector electrodes in a predetermined sequence (e.g., in the sequence of the collector electrodes 14L, 14C, and 14R).

According to this feature, before the quantity of afterglow of a region of the phosphor located in the vicinity of a certain collector electrode becomes excessively small, the region of the phosphor can emit light again through impingement of electrons thereon. As a result, uneven emission of light (uneven brightness) can be reduced.

The electron emission drive circuit 16 applies the electron emission voltage Vp to the electron emitter 12 only while the collector voltage Vc is applied to any of the plurality of collector electrodes (14L, 14C, and 14R). Additionally, the electron emission drive circuit 16 applies the write voltage Vm to the electron emitter 12 only while the collector voltage Vc is applied to none of the plurality of collector electrodes (14L, 14C, 14R).

This feature can avoid an occurrence in which, in spite of emission of no electrons, the collector voltage Vc is applied to any of the collector electrodes (14L, 14C, and 14R). As a result, wasteful consumption of power in the collector voltage application circuit (17) can be avoided. Additionally, while the collector voltage is applied to none of the plurality of collector electrodes (14L, 14C, and 14R) (during a period when there is no need to subject the phosphor to impingement of electrons), the write voltage is applied to the electron emitter 12 so that the electron emitter 12 can accumulate electrons therein. As a result, the light-emitting device 10 can efficiently accumulate electrons in the electron emitter 12 and can efficiently emit electrons from the electron emitter 12. Also, wear of the upper electrode 12c of the electron emitter 12 and dielectric breakdown of the electron emitter 12 can be prevented.

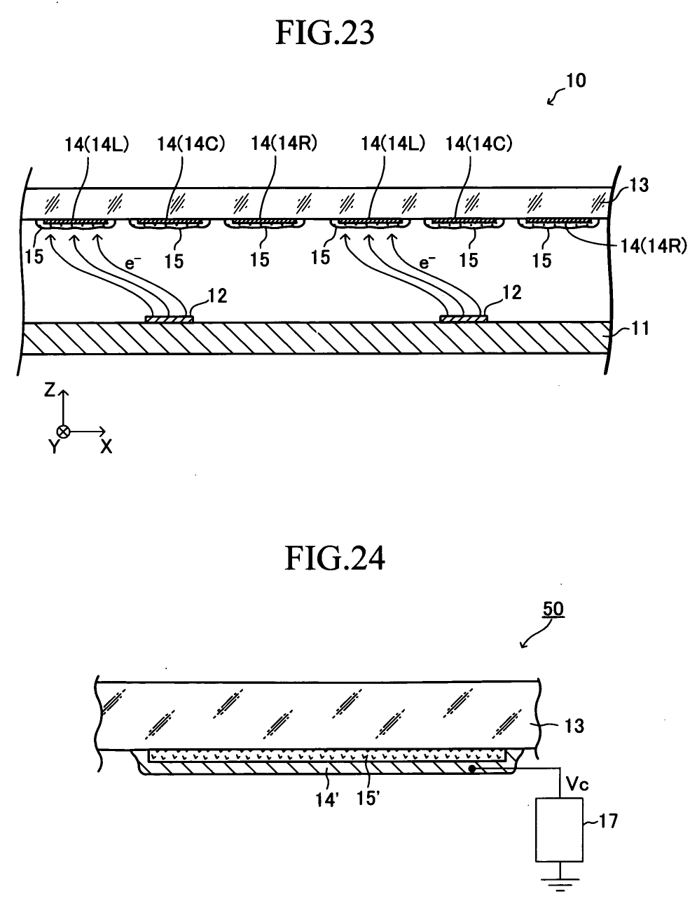

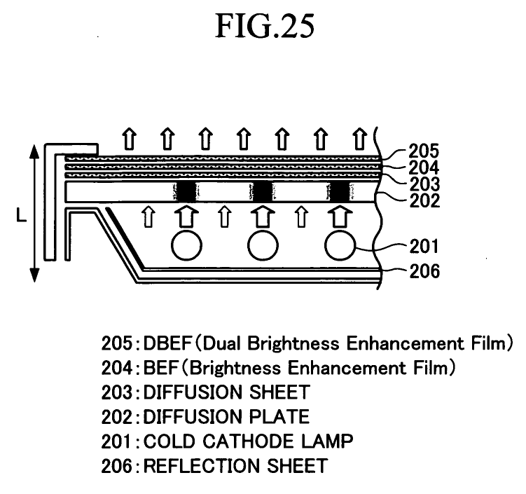

The present invention is not limited to the above embodiments, but may be modified as appropriate without departing from the scope of the invention. For example, in the light-emitting devices of the first to third embodiments employing the white phosphor, as shown in FIG. 23, each of the collector electrodes 14 may be independently covered with the white phosphor. Also, the structure having the reflection plate or the scattering plate shown in FIGS. 16 and 17 can be applied to a light-emitting device for use in a color display, such as the light-emitting device 50 of the fourth embodiment.

As shown in FIG. 24 fragmentarily showing a light-emitting device, the collector electrodes 14 and the phosphor 15 of, for example, the light-emitting device 10 may be replaced with collector electrodes 14′ and a phosphor 15′, respectively. Specifically, in the light-emitting device of FIG. 24, the phosphor 15′ is formed on the lower surface (a surface in opposition to the upper electrode 12c) of the transparent plate 13, and the collector electrodes 14′ are formed in such a manner as to cover the phosphor 15′. The collector electrodes 14′ have such a thickness as to allow passage therethrough of electrons which are emitted from the emitter section 12b through the fine through holes 12c1 of the upper electrode 12c. In this case, desirably, the collector electrodes 14′ have a thickness of 100 nm or less. The thickness of the collector electrodes 14′ can be increased with kinetic energy of emitted electrons.

The above-mentioned configuration is employed by a CRT or the like. The collector electrodes 14′ function as metal backing. Electrons which are emitted from the emitter section 12b through the fine through holes 12c1 of the upper electrode 12c pass through the collector electrodes 14′ and impinge on the phosphor 15′. The phosphor 15′ on which electrons impinge is excited and emits light. The light-emitting device can yield the following effects.
(a) In the case where the phosphor 15′ is not electrically conductive, electrification (negative electrification) of the phosphor can be avoided. As a result, an electric field for accelerating electrons can be maintained.
(b) Since the collector electrodes 14′ reflect light emitted from the phosphor 15′, the light can be efficiently directed toward the transparent plate 13 (toward a light-emitting surface).
(c) Since impingement of excess electrons on the phosphor 15′ can be prevented, deterioration of the phosphor 15′ and generation of gas from the phosphor 15′ can be avoided.

1. A light-emitting device comprising:
an electron emitter for accumulating therein a large number of electrons upon application of a predetermined write voltage thereto and for planarly emitting the accumulated large number of electrons from a planar electron-emitting section thereof upon application of a predetermined electron emission voltage thereto;
a plurality of collector electrodes disposed in opposition to the electron-emitting section and adapted to attract, upon application of a predetermined collector voltage thereto, electrons emitted from the electron emitter;
a phosphor disposed in the vicinity of the plurality of collector electrodes and emitting light through impingement of electrons thereon;
an electron emission drive circuit for alternately applying the write voltage and the electron emission voltage to the electron emitter; and
a collector voltage application circuit for applying the collector voltage to the plurality of collector electrodes in respective different periods of time when the electron emitter is emitting electrons.

2. A light-emitting device according to claim 1, wherein during application of the collector voltage to one of the plurality of collector electrodes, the collector voltage application circuit does not apply the collector voltage to the remaining collector electrodes.

3. A light-emitting device according to claim 1, wherein the collector voltage application circuit repeats an operation of applying the collector voltage to each of the plurality of collector electrodes in a predetermined sequence.

4. A light-emitting device according to claim 1, wherein the electron emission drive circuit applies the electron emission voltage to the electron emitter only while the collector voltage is applied to any of the plurality of collector electrodes, and applies the write voltage to the electron emitter only while the collector voltage is applied to none of the plurality of collector electrodes.

5. A light-emitting device according to claim 1, wherein the collector voltage application circuit applies the collector voltage at least once to each of the plurality of collector electrodes during a period of time between start and end of application of the electron emission voltage by the electron emission drive circuit.

6. A light-emitting device according to claim 1, wherein the phosphor is a white phosphor for emitting white light.

7. A light-emitting device according to claim 1, wherein a plurality of the phosphors are provided, and the plurality of phosphors are disposed in the vicinity of the corresponding collector electrodes and emit light in different colors.

8. A light-emitting device according to claim 1, wherein the collector electrodes are provided in a number of at least three; the phosphors are provided in a number of at least three; the three phosphors are disposed in the vicinity of the corresponding three collector electrodes; one of the three phosphors is a red phosphor for emitting red light; another one of the three phosphors is a green phosphor for emitting green light; and the remaining one of the three phosphors is a blue phosphor for emitting blue light.

9. A light-emitting device according to claim 1, further comprising a sheet-like transparent plate having a lower surface in opposition to the electron-emitting section and in parallel with a plane of the electron-emitting section, a reflection plate or a scattering plate, and a plurality of the electron emitters,
wherein the plurality of collector electrodes, and the phosphor are formed on the lower surface of the transparent plate;
the reflection plate or the scattering plate is disposed at a position of no hindrance to travel of electrons emitted from the electron emitters and directed toward the plurality of collector electrodes, and in opposition to the transparent plate and the collector electrodes; and
the transparent plate has a light transmission portion formed at a position located between an end collector electrode of one group of collector electrodes attracting electrons emitted from a first one of the plurality of electron emitters and an end collection electrode, adjacent to the first-mentioned end collector electrode, of another group of collector electrodes attracting electrons emitted from a second one of the plurality of electron emitters, the light transmission portion allowing transmission therethrough of light reflected from the reflection plate or the scattering plate.

10. A light-emitting device according to claim 1, wherein the electron emitter comprises an emitter section formed of a sheet-like dielectric material, a lower electrode formed under the emitter section, and an upper electrode serving as the electron-emitting section, formed on the emitter section in such a manner as to face the lower electrode with the emitter section sandwiched therebetween, and having a plurality of fine through holes formed therein; accumulates, when the write voltage is applied between the lower electrode and the upper electrode, the large number of electrons at an upper portion of the emitter section through negative-side polarization inversion of the emitter section effected by the write voltage; and planarly emits, when the electron emission voltage is applied between the lower electrode and the upper electrode, the accumulated large number of electrons through the fine though holes of the upper electrode through positive-side polarization inversion of the emitter section effected by the electron emission voltage.
